(19) United States
(12) Patent Application Publication
(10) Pub. No.: US 2023/0197818 A1
(43) Pub. Date: Jun. 22, 2023

(54) FORMATION OF CAVITY SPACER AND SOURCE-DRAIN EPITAXIAL GROWTH FOR SCALING OF GATE-ALL-AROUND TRANSISTORS

(71) Applicant: Intel Corporation, Santa Clara, CA (US)

(72) Inventors: Nitesh Kumar, Beaverton, OR (US); William Hsu, Portland, OR (US); Mohammad Hasan, Aloha, OR (US); Ritesh Das, Hillsboro, OR (US); Vivek Thirtha, Portland, OR (US); Biswajeet Guha, Hillsboro, OR (US); Oleg Golonzka, Beaverton, OR (US)

(73) Assignee: Intel Corporation, Santa Clara, CA (US)

(21) Appl. No.: 17/559,342

(22) Filed: Dec. 22, 2021

(51) Int. Cl. H01L 29/423; H01L 29/786; H01L 29/66; H01L 21/8234

(52) U.S. Cl. CPC H01L 29/42392; H01L 29/78618; H01L 29/78696; H01L 29/66742; H01L 21/823412; H01L 21/823418

(57) ABSTRACT

Methods, integrated circuit devices, and systems are discussed related to combining source and drain etch, cavity spacer formation, and source and drain semiconductor growth into a single lithographic processing step in gate-all-around transistors. Such combined processes are performed separately for NMOS and PMOS gate-all-around transistors by implementing selective masking techniques. The resulting transistor structures have improved cavity spacer integrity and contact to gate isolation.

### BACKGROUND

In stacked nanosheet gate-all-around (GAA) transistors, the epitaxial (EPI) material of the source and drain needs to be isolated from the metal gate to prevent contact to gate shorting. Typically, such isolation is achieved by performing a source-drain vertical etch, followed by cavity formation, and filling the cavity with dielectric material (i.e., a cavity spacer). Subsequently, NMOS (n-type metal oxide semiconductor) and PMOS (p-type metal oxide semiconductor) devices are created by using lithographic patterning to grow respective source and drain epitaxial films. Such source and drain epitaxial patterning processes can become challenging with very narrow source and drain openings, difficulties including trapped patterning films that can prevent epitaxial material growth, and other problems. Furthermore, using such techniques, the cavity spacer is exposed to patterning wet cleans, which can lead to erosion, failed contact to gate isolation, and other problems.

It is desirable to increase the reliability of the cavity spacer to prevent contact to gate shorting, and to prevent the failure epitaxial growth on the channel material due to trapped patterning films, and other difficulties. It is with respect to these and other considerations that the present improvements have been needed. Such improvements may become critical as the desire to implement GAA transistors in a variety of high performance integrated circuit electronic devices becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram illustrating an example process for fabricating integrated circuit structures using a single lithographic patterning process for forming cavity spacers and source and drain materials in gate-all-around transistors of each conductivity type;

FIGS. 2A, 2B, 2C, 2D, 2E, 2F, 2G, 2H, 2I, 2J, 2K, and 2L illustrate selected views of example integrated circuit structures as particular fabrication operations of the process of FIG. 1 are performed;

FIG. 3 illustrates a flow diagram illustrating another example process for fabricating integrated circuit structures using a single lithographic patterning process for forming cavity spacers and source and drain materials in gate-all-around transistors of each conductivity type;

FIGS. 4A, 4B, 4C, 4D, 4E, 4F, 4G, 4H, 4I, 4J, 4K, and 4L illustrate selected views of example integrated circuit structures as particular fabrication operations of the process of FIG. 3 are performed;

FIG. 5 is an illustrative diagram of a mobile computing platform employing an integrated circuit device with gate-all-around transistors formed by combining source and drain etch, cavity spacer formation, and source and drain semiconductor growth; and

FIG. 6 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. As used herein, the terms “monolithic”, “monolithically integrated”, and similar terms indicate the components of the monolithic overall structure form a indivisible whole not reasonably capable of being separated.

Integrated circuit device structures, transistors, systems, and methods are described herein related to forming high quality cavity spacers and source drain epitaxial materials for gate-all-around transistors.

As discussed, in stacked nanosheet gate-all-around (GAA) transistors, the epitaxial (EPI) material of the source and drain needs to be isolated from the metal gate to prevent contact to gate shorting. In typical processing, after formation of cavity spacers adjacent sacrificial layers that are between the channel material layers of the transistor, the region adjacent the cavity spacers is exposed several times to form other structures of the transistor. Such source and drain epitaxial patterning processing has difficulties including very narrow source and drain openings, trapping of patterning films that prevent epitaxial material growth, erosion of the cavity spacer due to exposure particularly during patterning wet cleans, others. In some embodiments, the source and drain etch, cavity spacer formation, and source and drain epitaxial material growth processing are all provided during a single lithographic patterning process performed for each of the NMOS and PMOS transistors. For example, the NMOS transistors may be masked and such processing is performed for PMOS transistors and, subsequently the PMOS transistors are masked and such processing is performed for NMOS transistors, or vice versa. Such techniques provide for high quality cavity spacers and epitaxial materials for GAA transistors in narrow source and drain openings to achieve low contact-gate leakage through improved contact-gate isolation. Such techniques may be employed to enable ever narrower gate-pitches for higher transistor densities.

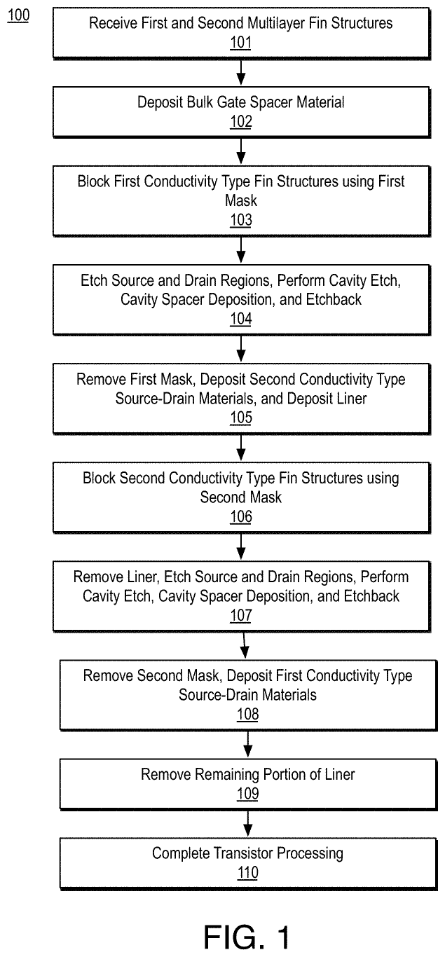

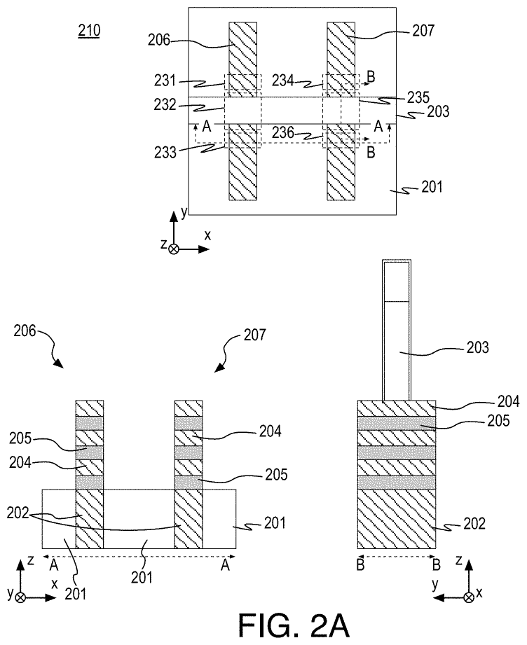

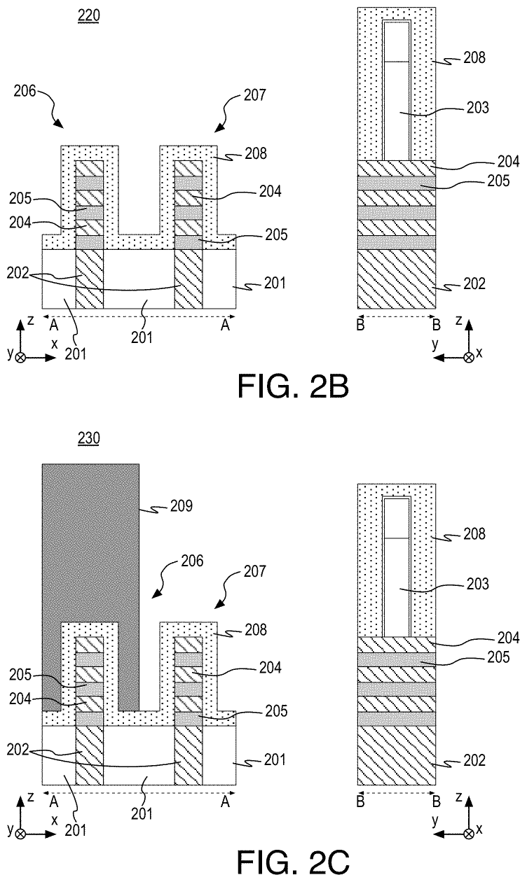

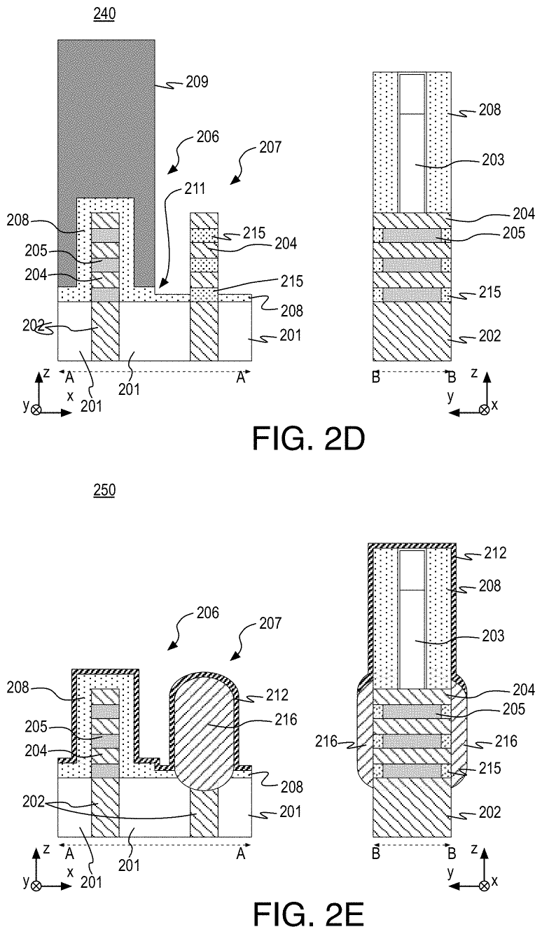

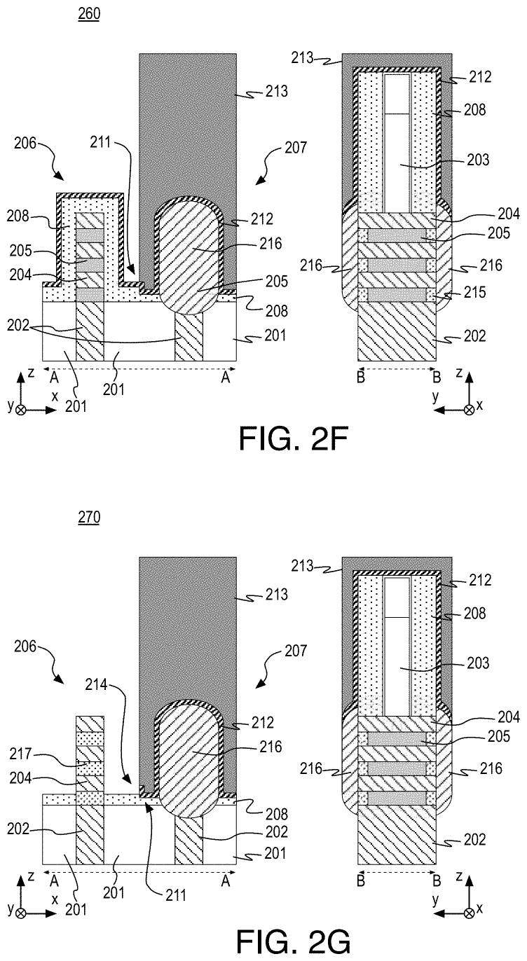

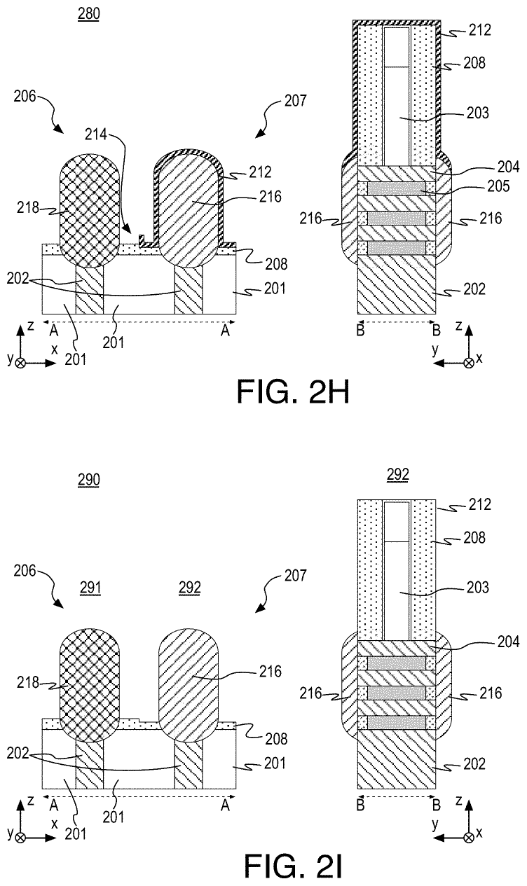

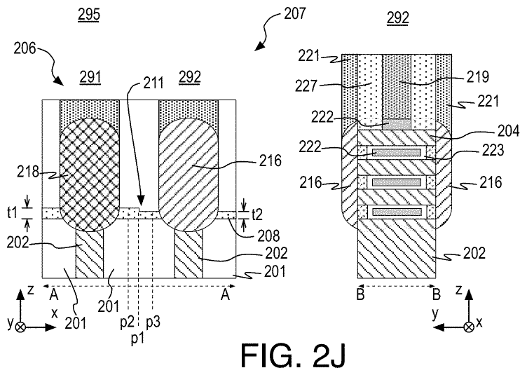

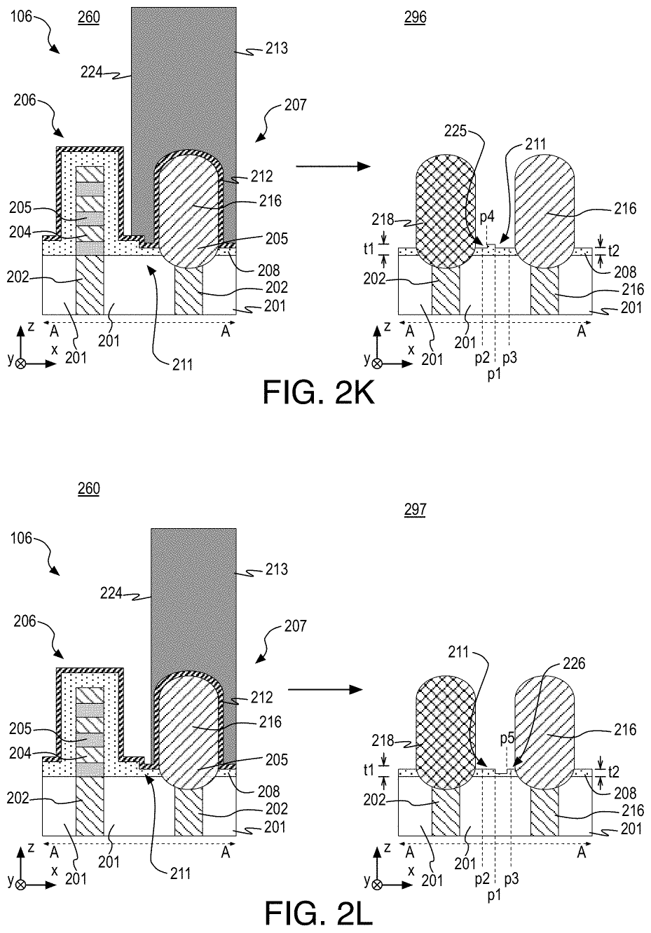

FIG. 1 illustrates a flow diagram illustrating an example process 100 for fabricating integrated circuit structures using a single lithographic patterning process for forming cavity spacers and source and drain materials in gate-all-around transistors of each conductivity type, arranged in accordance with at least some implementations of the present disclosure. As used herein, the term conductivity type indicates one of n-type or p-type conductivity. For example, process 100 may be implemented to fabricate integrated circuit structures 295, 296, 297, or any other integrated circuit structures discussed herein. In the illustrated embodiment, process 100 includes one or more operations as illustrated by operations 101-110. However, embodiments herein may include additional operations, certain operations being omitted, or operations being performed out of the order provided. In an embodiment, process 100 may fabricate integrated circuit structures 295, 296, 297 or a similar integrated circuit structure as discussed with respect to FIGS. 2A-2L.

FIGS. 2A, 2B, 2C, 2D, 2E, 2F, 2G, 2H, 2I, 2J, 2K, and 2L illustrate selected views of example integrated circuit structures as particular fabrication operations of process 100 are performed, arranged in accordance with at least some implementations of the present disclosure. In particular, reference will be made to FIGS. 2A, 2B, 2C, 2D, 2E, 2F, 2G, 2H, 2I, 2J, 2K, and 2L in the context of process 100.

Process 100 begins at operation 101, where a number of multilayer fin structures over a substrate are received for processing. For example, any number of fin structures may be formed using known techniques on or over a substrate. In some embodiments, a multilayer stack of alternating first and second materials are bulk deposited over a substrate and patterned to form the multilayer fin structures. For example, the multilayer fin structures may include a subfin adjacent isolation materials and alternating first and second materials over the subfin and extending above the isolation materials. In some embodiments, the first material is the material chosen to be the channel material of the transistors and the second material is a sacrificial material to be removed and replaced by gate dielectric and gate metal.

Referring now to FIG. 2A, an example integrated circuit structure 210 (e.g., IC structure work piece) is illustrated in top down view and at cross sectional views A-A and B-B illustrated in the top down view. For example, cross sectional view A-A is taken at a source or drain cut across two adjacent multilayer fin structures 206, 207. Notably, a GAA transistor of a first type (i.e., NMOS) is to be formed using multilayer fin structure 206 and a GAA transistor of a second type (i.e., PMOS) is to be formed using multilayer fin structure 207. Although illustrated herein below with respect to multilayer fin structure 206 being blocked first and multilayer fin structure 207 second, such processing may be reversed. Cross sectional view B-B is taken along a fin cut of multilayer fin structure 207. Herein below, source or drain cut and fin cut views are illustrated for the sake of clarity; however, top-down views are not illustrated for the sake of brevity.

As shown, integrated circuit structure 210 includes multilayer fin structures, 206, 207 including subfins 202 that are isolated by isolation materials 201. Isolation materials 201 may include any suitable dielectric materials such as silicon oxide. For example, isolation materials 201 may include silicon and oxygen. As shown, multilayer material stacks of channel semiconductor layers 204 and sacrificial material layers 205 extend above subfins 202. For example, channel semiconductor layers 204 are to remain as the channel layers of eventual GAA transistors while sacrificial material layers 205 will be removed and replaced by gate structures. Furthermore, prior to formation of the gate structures, sacrificial material layers 205 are recessed to form cavity spacers such that eventual source and drain materials are isolated from the gate contacts of the gate structures.

Multilayer fin structures 206, 207 are over a substrate (not shown) and subfins 202 may be continuous with the substrate material of the substrate. The substrate may include any suitable material or materials and, in some embodiments, the substrate includes a material or materials having the same or a similar composition with channel semiconductor layers 204 of multilayer fin structures 206, 207. In some embodiments, the substrate and channel semiconductor layers 204 include a Group IV material (e.g., silicon). In some embodiments, the substrate and channel semiconductor layers 204 include a substantially monocrystalline material. In some embodiments, the substrate includes a buried insulator layer (e.g., SiO₂), for example, of a semiconductor-on-insulator (SOI) substrate and or isolation insulator regions and the like. Channel semiconductor layers 204 may include any number of channel semiconductors, ribbons, or layers over the substrate such as three, four, five, or more layers Channel semiconductor layers 204 are separated by sacrificial material layers 205, which will later be removed and replaced by one or more gate structures inclusive of, for example, gate dielectric materials and gate electrode materials. In some embodiments, channel semiconductor layers 204 include silicon (e.g., monocrystalline silicon, Si) and sacrificial material layers 205 include silicon and germanium (e.g., silicon germanium, SiGe).

As shown in the top down view, multilayer fin structure 206 includes gate region 232 and source and drain regions 231, 233. Notably, gate structures will be formed in gate region 232, which will include channel semiconductor layers 204 and source and drain semiconductor material will be formed (e.g., epitaxially deposited) in source and drain regions 231, 233. For, example, NMOS source and drain semiconductor material is to be formed in source and drain regions 231, 233 (i.e., n-type semiconductor source and drain material). Similarly, multilayer fin structure 207 includes gate region 235 and source and drain regions 234, 236. Notably, gate structures will be formed in gate region 235, which will include channel semiconductor layers 204 and source and drain semiconductor material will be formed (e.g., epitaxially deposited) in source and drain regions 234, 236. For, example, PMOS source and drain semiconductor material is to be formed in source and drain regions 234, 236 (i.e., p-type semiconductor source and drain material). Between gate regions 232, 235 and respective ones of source and drain regions 231, 233, 234, 236, it is important to isolate the source and drain materials from gate contacts using cavity spacers and other materials. The techniques discussed herein provide for improved cavity spacer robustness and therefore improved isolation by reducing the amount of processing the cavity spacers are exposed to. As shown, in gate regions 232, 235, sacrificial gate structure 203 is provided to protect channel semiconductor layers 204 and sacrificial material layers 205 under sacrificial gate structure 203.

Returning to FIG. 1, processing continues at operation 102, where a gate spacer material is conformally deposited over the received work piece including the multilayer fin structures. The gate spacer may be deposited using any suitable technique or techniques such as chemical vapor deposition (CVD), physical vapor deposition (PVD), atomic layer deposition (ALD), or similar techniques. The gate spacer material, provided as a conformal dielectric layer at operation 102 will eventually provide a spacer between a gate contact and source and drain contacts.

FIG. 2B illustrates an example integrated circuit structure 220 similar to integrated circuit structure 210 after deposition of a conformal gate spacer dielectric material layer 208. As shown, a conformal dielectric material layer 208 is formed over sacrificial gates 203, multilayer fin structures 206, 207 and isolation material 201. Conformal dielectric material layer 208 may include any suitable dielectric material. In some embodiments, conformal dielectric material layer 208 is a low-k dielectric material (e.g., a dielectric material having a small relative dielectric constant relative to silicon dioxide). In some embodiments, conformal dielectric material layer 208 includes one or more of silicon, oxygen, carbon and nitrogen. In some embodiments, conformal dielectric material layer 208 is a material including silicon and oxygen (e.g., silicon oxide, SiO₂). In addition to silicon and oxygen, conformal dielectric material layer 208 may include nitrogen (e.g., silicon oxynitride) or carbon (e.g., silicon oxycarbide). In some embodiments, conformal dielectric material layer 208 is a multilayer stack of alternating dielectric materials (of the same or differing thicknesses).

Returning to FIG. 1, processing continues at operation 103, where a first mask is formed to selectively expose first multilayer fin structures (PMOS transistors or NMOS transistors) and cover second multilayer fin structures (the other of NMOS or PMOS transistors). Herein, NMOS transistor multilayer fin structures are first blocked or covered; however, the processing order may be reversed. As used herein, the terms block and expose indicate the corresponding multilayer fin structures are under the mask, or not. Notably, exposed multilayer fin structures may have other materials thereon. The first mask may be formed using any suitable technique or techniques such as photolithography techniques (e.g., resist deposition, expose, develop) and the first mask may be any suitable material or materials such as resist materials, hard mask materials, etc.

FIG. 2C illustrates an example integrated circuit structure 230 similar to integrated circuit structure 220 after formation of first mask 209 to block multilayer fin structures 206 and to expose multilayer fin structures 207. As shown, multilayer fin structures 206 are under first mask 209 and are therefore blocked by first mask 209 while multilayer fin structures 207 are not under first mask 209 and are therefore exposed by first mask 209 (although a portion of conformal dielectric material layer 208 is over multilayer fin structures 207). As discussed, first mask 209 may be formed using photolithography techniques and may include any suitable material or materials to protect regions under first mask 209 during subsequent processing. Furthermore, first mask 209 may have any thickness to properly mask such regions.

Returning to FIG. 1, processing continues at operation 104, where a source and drain etch is performed to remove portions of the multilayer fin structures adjacent the channel regions thereof, a cavity etch is performed to recess the sacrificial materials of the multilayer fin structures, the cavity spacer materials are deposited, and the cavity spacer materials are etched back to provide cavity spacers in the recesses of the sacrificial materials of the multilayer fin structures. As discussed, using the techniques discussed herein, such cavity spacers (and subsequent source and drain materials) are formed using a single patterning operation to maintain the integrity of the cavity spacers. Such operations may be performed using any suitable technique or techniques.

In some embodiments, the source and drain etch is performed using anisotropic etch techniques selective to the materials of the multilayer fin structures (e.g., Si and SiGe). Such etch processing removes the multilayer fin structures in the source and drain regions (e.g., source and drain regions 234, 236; refer to FIG. 2a) and exposes the channel semiconductor material layers and sacrificial layers via those removed regions. The remaining channel semiconductor material layers and sacrificial layers may be characterized as multilayer channel structures as they include the channel materials of the eventual GAA transistors. After the source and drain etch, a cavity etch is performed to recess the sacrificial materials of the multilayer fin structures. The cavity etch may be performed using any suitable technique or techniques such as timed isotopic etch techniques selective to the sacrificial materials of the multilayer fin structures. For example, an isotropic SiGe etch may be deployed. The resultant cavities or recesses adjacent the sacrificial materials of the multilayer fin structures are then filled via cavity spacer material deposition and etch back techniques. For example, the cavity spacer material may be conformally deposited to a particular thickness and a time etch may be performed to remove a portion of the thickness, leaving the cavity spacers. The cavity spacer electrically isolates the subsequently formed source and drain semiconductor and gate metal.

FIG. 2D illustrates an example integrated circuit structure 240 similar to integrated circuit structure 230 after removal of portions of the multilayer fin structures in the source and drain regions, and formation of cavity spacers 215 in recesses formed adjacent sacrificial material layers 205. For example, with reference to the top down view provided in FIG. 2a, the portions of multilayer fin structure 207 in source and drain regions 234, 236 are removed while multilayer fin structure 206 is protected by first mask 209 and gate region 235 of multilayer fin structure 207 is protected by sacrificial gate 203. Subsequently, sacrificial material layers 205 are recessed using a selective recess etch as discussed, such that channel semiconductor layers 204 are substantially unaffected. Such recesses are then filled by cavity spacers 215. Cavity spacers 215 are formed using deposition and etch back techniques.

As shown, processing the removal of portions of the multilayer fin structures in source and drain regions 234, 236 also removes portions of dielectric material layer 208. Such removal of portions of dielectric material layer 208 may be provided as part of the etching of portions of the multilayer fin structures in source and drain regions 234, 236 or as pre-processing for the removal of portions of the multilayer fin structures in source and drain regions 234, 236. As shown, such processing advantageously removes dielectric material layer 208 in source and drain regions 234, 236 and forms a thickness transition 211 in dielectric material layer 208 over isolation material 201. As shown, dielectric material layer 208 has a first thickness adjacent multilayer fin structure 206 that is thicker than a second thickness of dielectric material layer 208 adjacent multilayer fin structure 207. That is, dielectric material layer 208 has a second thickness less than the first thickness the first and second thicknesses separated by thickness transition 211. Notably, thickness transition 211 is at an edge of first mask 209.

Cavity spacers 215 may include any suitable material or materials. In some embodiments, cavity spacers 215 include a similar material to that of dielectric material layer 208 but with a different composition. For example, cavity spacers 215 may include any suitable dielectric material. In some embodiments, cavity spacers 215 include a low-k dielectric material. In some embodiments, cavity spacers 215 include one or more of silicon, oxygen, carbon and nitrogen. In some embodiments, cavity spacers 215 deploy a material including silicon and oxygen (e.g., silicon oxide, SiO₂). In addition to silicon and oxygen, dielectric material layer 208 may include nitrogen (e.g., silicon oxynitride) or carbon (e.g., silicon oxycarbide). In some embodiments, dielectric material layer 208 and cavity spacers 215 deploy the same material.

Multilayer fin structure 207 (or multilayer channel structure) of integrated circuit structure 240 is thereby prepared for application of a source and drain material for an eventual GAA semiconductor device. Notably, channel semiconductor layers 204 are exposed in source and drain regions 234, 236 while sacrificial material layers 205 are not. Instead, sacrificial material layers 205 are covered by cavity spacers 215. Source and drain materials may then be formed on channel semiconductor layers 204 while regions for the formation of eventual gate structures (e.g., when sacrificial material layers 205 are removed and replaced by gate structures) are isolated by cavity spacers 215.

Returning to FIG. 1, processing continues at operation 105, where the first mask is removed, source and drain semiconductor materials suitable for the conductivity type of the GAA transistor being formed are deposited (e.g., epitaxially grown), and a protective liner is formed on the resultant source and drain semiconductor materials. The first mask may be removed using any suitable technique or techniques such as ash processing techniques. The resultant structure provides transistor channel materials exposed for one conductivity type (e.g., PMOS) of transistor while the source and drain regions have not been removed for the other conductivity type (e.g., NMOS) transistor type. Epitaxial source and drain semiconductor materials may then be selectively formed on the exposed transistor channel materials (e.g., channel silicon). Such epitaxial growth techniques may be performed using any suitable technique or techniques. In some embodiments, vapor phase epitaxy is deployed. In some embodiments, the epitaxial growth includes molecular beam epitaxy techniques. Such epitaxial growth is selective to exposed crystal surfaces of the channel semiconductor and grows substantially crystalline source and drain materials that are epitaxial to (e.g., share a crystal orientation with) the channel semiconductor. The protective liner may be formed using any suitable technique or techniques such as CVD, PVD, ALD, or similar techniques.

FIG. 2E illustrates an example integrated circuit structure 250 similar to integrated circuit structure 240 after the removal of first mask 209, the formation of source and drain semiconductor 216, and the formation of liner material 212. As discussed, first mask 209 may be removed using any suitable technique or techniques such as ash processing. Source and drain semiconductor 216 may be formed using any suitable technique or techniques such as vapor phase epitaxy techniques, molecular beam epitaxy techniques, or other epitaxial growth techniques. As shown, source and drain semiconductor 216 grows epitaxially from exposed channel semiconductor layers 204. Source and drain semiconductor 216 may include faceting and growth structures and characteristics as known in the art. Source and drain semiconductor 216 may include any suitable material or materials for the conductivity type of GAA being formed. In some embodiments, for NMOS GAA transistors, source and drain semiconductor 216 is epitaxial silicon doped with n-type dopants inclusive of phosphorous, arsenic, antimony, or others. For example, NMOS source and drain semiconductor materials may include silicon and one or more of phosphorous, arsenic, and antimony. In some embodiments, for PMOS GAA transistors, source and drain semiconductor 216 is epitaxial silicon germanium doped with p-type dopants inclusive of boron, aluminum, gallium, indium, or others. For example, PMOS source and drain semiconductor materials may include silicon and germanium, and one or more of boron, aluminum, gallium, and indium. In the illustrated example, source and drain semiconductor 216 is p-type; however, as discussed the processing order of NMOS and PMOS GAA transistors may be reversed.

Subsequent epitaxial growth of source and drain semiconductor 216, a conformal liner material 212 is formed over the exposed surfaces of source and drain semiconductor 216 and dielectric material layer 208. Liner material 212 may be formed using any suitable technique or techniques such as CVD, PVD, ALD, or similar techniques to any suitable thickness such as a thickness in the range of 2 to 30 nm. Liner material 212 may be any suitable material that provides protection for source and drain semiconductor 216 and blocks epitaxial growth thereon. In some embodiments, liner material 212 is a dielectric oxide (e.g., silicon oxide, silicon oxynitride, silicon oxycarbide, etc.). In some embodiments, liner material 212 is a metal oxide (e.g., aluminum oxide). For example, liner material 212 may include oxygen and one or more of silicon, nitrogen, or aluminum.

Returning to FIG. 1, processing continues at operation 106, where a second mask is formed to selectively expose second multilayer fin structures (i.e., for NMOS transistors if PMOS transistors have been processed or vice versa) and cover first multilayer fin structures (the other of NMOS or PMOS transistors). As discussed either or NMOS or PMOS GAA transistors may be processed first. In the following, the convention that PMOS transistors are processed first is maintained for the sake of clarity. The second mask may be formed using any suitable technique or techniques such as photolithography techniques and the second mask may be any suitable material or materials such as resist materials, hard mask materials, etc.

FIG. 2F illustrates an example integrated circuit structure 260 similar to integrated circuit structure 250 after formation of second mask 213 to block multilayer fin structures 207 and to expose multilayer fin structures 206. Multilayer fin structures 207 are under second mask 213 and are therefore blocked by second mask 213 while multilayer fin structures 206 are not under second mask 213 and are therefore exposed by second mask 213 (although a portion of dielectric material layer 208 and a portion of liner material 212 are over multilayer fin structures 206). As discussed, second mask 213 may be formed using photolithography techniques and may include any suitable material or materials to protect regions under second mask 213 during subsequent processing. Furthermore, second mask 213 may have any thickness to properly mask such regions. In the example of FIG. 2F, an edge of second mask 213 is aligned with thickness transition 211.

Returning to FIG. 1, processing continues at operation 107, where exposed portions of the liner material are removed, a source and drain etch removes portions of the multilayer fin structures adjacent the channel regions thereof, a cavity etch is performed to recess the sacrificial materials of the multilayer fin structures, the cavity spacer materials are deposited, and the cavity spacer materials are etched back to provide cavity spacers in the recesses of the sacrificial materials of the multilayer fin structures. As discussed, such cavity spacers (and subsequent source and drain materials) are formed using a single patterning operation to maintain the integrity of the cavity spacers. The exposed liner material may be removed using any suitable technique or techniques such as wet etch techniques. In some embodiments, the source and drain etch is performed using anisotropic etch techniques to selectively the materials of the multilayer fin structures in the exposed source and drain regions (e.g., regions 231, 233; refer to FIG. 2a). Such source and drain etch exposes the channel semiconductor material layers and sacrificial layers via those removed portions of the multilayer fin structures in those source and drain regions. The remaining channel semiconductor material layers and sacrificial layers may be characterized as multilayer channel structures.

After the source and drain etch, a cavity etch is performed to recess the sacrificial materials of the multilayer fin structures and a cavity spacer is formed. The cavity etch may be performed using any suitable technique or techniques such as selective etch techniques. The resultant cavities or recesses adjacent the sacrificial materials of the multilayer fin structures are then filled via cavity spacer material deposition and etch back techniques inclusive of cavity spacer material deposition and etch back.

FIG. 2G illustrates an example integrated circuit structure 270 similar to integrated circuit structure 260 after removal of exposed portions of liner material 212, removal of portions of dielectric material layer 208, removal of portions of multilayer fin structures 206 in the exposed source and drain regions, and formation of cavity spacers 217 in recesses formed adjacent sacrificial material layers 205. As shown, removal of liner material 212 leaves a liner edge 214. In the illustrated example, the removal dielectric material layer 208 (as a separate operation or as part of the removal of portions of multilayer fin structures 206) does not remove as much material from over isolation material 201 as discussed with respect to the removal operation of FIG. 2D such that thickness transition 211 is maintained with a thicker portion of dielectric material layer 208 adjacent multilayer fin structure 206 and thinner portion of dielectric material layer 208 adjacent source and drain semiconductor 216 and multilayer fin structure 207. In other embodiments, the removal dielectric material layer 208 may exceed that of the previous removal such that a thinner portion of dielectric material layer 208 is adjacent multilayer fin structure 206 and thicker portion of dielectric material layer 208 is adjacent source and drain semiconductor 216 and multilayer fin structure 207, such that the location of thickness transition 211 is maintained.

With reference to the top down view provided in FIG. 2A, the portions of multilayer fin structure 206 in source and drain regions 231, 233 are removed while multilayer fin structure 207 is protected by second mask 213 and gate region 232 of multilayer fin structure 206 is protected by sacrificial gate 203. Subsequently, sacrificial material layers 205 are recessed using a selective recess etch such that channel semiconductor layers 204 are substantially unaffected. Such recesses are then filled by cavity spacers 217. Cavity spacers 217 are formed using deposition and etch back techniques. Notably, in a cross section orthogonal to cross section A-A cut along multilayer fin structure 206, a view analogous to that of cross section B-B is provided for multilayer fin structure 206 (refer to FIG. 2D, cross section B-B).

Cavity spacers 217 may include any suitable material or materials discussed with respect to cavity spacers 215. In some embodiments, cavity spacers 217 include a similar material to that of dielectric material layer 208 but with a different composition. For example, cavity spacers 217 may include any suitable dielectric material such as a low-k dielectric material. In some embodiments, cavity spacers 217 include one or more of silicon, oxygen, carbon and nitrogen.

For example, cavity spacers 217 may deploy a material including silicon and oxygen (e.g., silicon oxide, SiO₂), a material including silicon, oxygen, and nitrogen (e.g., silicon oxynitride), or material including silicon, oxygen, and carbon (e.g., silicon oxycarbide). In some embodiments, cavity spacers 217 and cavity spacers 215 deploy the same material. In some embodiments, cavity spacers 217, cavity spacers 215, and dielectric material layer 208 deploy the same material.

Multilayer fin structure 206 (or multilayer channel structure) of integrated circuit structure 240 is thereby ready for application of a source and drain material such that channel semiconductor layers 204 are exposed in source and drain regions 231, 233 while sacrificial material layers 205 are covered by cavity spacers 217. Source and drain materials may then be formed on channel semiconductor layers 204 while regions for the formation of eventual gate structures (e.g., when sacrificial material layers 205 are removed and replaced by gate structures) are isolated by cavity spacers 217.

Returning to FIG. 1, processing continues at operation 108, where the second mask is removed, and source and drain semiconductor materials suitable for the conductivity type of the GAA transistor being formed are deposited (e.g., epitaxially grown). The second mask may be removed using any suitable technique or techniques such as ash processing techniques. The resultant structure provides transistor channel materials exposed for a second type (e.g., NMOS) of transistor while the source and drain regions have already been deposited for the other type (e.g., PMOS) transistor type and are covered by the liner material. Epitaxial source and drain semiconductor materials may then be selectively formed on the exposed transistor channel materials (e.g., channel silicon). Such epitaxial growth techniques may be performed using any suitable technique or techniques. In some embodiments, vapor phase epitaxy is deployed. In some embodiments, the epitaxial growth includes molecular beam epitaxy techniques. Such epitaxial growth is selective to exposed crystal surfaces of the channel semiconductor and grows substantially crystalline source and drain materials that are epitaxial to (e.g., share a crystal orientation with) the channel semiconductor.

FIG. 2H illustrates an example integrated circuit structure 280 similar to integrated circuit structure 270 after the removal of second mask 213 and the formation of source and drain semiconductor 218. Second mask 213 may be removed using any suitable technique or techniques such as ash processing. Source and drain semiconductor 218 may be formed using any suitable technique or techniques such as vapor phase epitaxy techniques, molecular beam epitaxy techniques, or other epitaxial growth techniques. As shown, source and drain semiconductor 218 grows epitaxially from exposed channel semiconductor layers 204 of multilayer fin structures 206. Notably, source and drain semiconductor 216 is covered by liner material 212 such that growth does not occur on source and drain semiconductor 216. Source and drain semiconductor 218 may include faceting and growth structures and characteristics as known in the art.

Source and drain semiconductor 218 may include any suitable material or materials for the conductivity type of GAA being formed. For example, for NMOS GAA transistors, source and drain semiconductor 218 may be epitaxial silicon doped with n-type dopants inclusive of phosphorous, arsenic, antimony, or others. For PMOS GAA transistors, source and drain semiconductor 216 may epitaxial silicon germanium doped with p-type dopants inclusive of boron, aluminum, gallium, indium, or others. In the illustrated example, source and drain semiconductor 218 is n-type; however, as discussed the processing order of NMOS and PMOS GAA transistors may be reversed. Notably, in a cross section orthogonal to cross section A-A cut along multilayer fin structure 206, a view analogous to that of cross section B-B is provided for multilayer fin structure 206 (refer to FIG. 2E, cross section B-B).

Returning to FIG. 1, processing continues at operation 109, where the remaining portion of the liner material is removed. The exposed line material may be removed using any suitable technique or techniques such as wet etch techniques.

FIG. 2I illustrates an example integrated circuit structure 290 similar to integrated circuit structure 280 after the removal of the remaining portion of liner material 212. As discussed, liner material 212 may be removed using any suitable technique or techniques such as wet etch techniques.

Returning to FIG. 1, processing continues at operation 110, where the transistor processing may be completed. Such processing may be performed using any suitable technique or techniques. In some embodiments, the sacrificial layers adjacent the channel semiconductor and the dummy gate materials may be replaced with gate structures using any suitable technique or techniques known in the art. For example, the sacrificial layers may be selectively etched and the requisite structures may be formed via deposition and optional patterning techniques. Furthermore, source and drain semiconductors and gate structures may be contacted by metal contacts using any suitable technique or techniques such as patterning and metal deposition processing known in the art.

FIG. 2J illustrates an example integrated circuit structure 295 similar to integrated circuit structure 290 after formation of source and drain contacts 221, gate contact 219, gate spacers 227, gate electrodes or gate metal 222, and gate dielectric 223 to form PMOS transistor 292 and NMOS transistor 291. It is noted that, in a cross section orthogonal to cross section A-A cut along multilayer fin structure 206 (and NMOS transistor 291), a view analogous to that of cross section B-B is provided for NMOS transistor 291. Such gate electrodes 222 and gate dielectric 223 may be formed using any suitable technique or techniques such as replacement gate techniques. Furthermore, such source and drain contacts 221 and gate contact 219 may be formed using any suitable technique or techniques such as patterning, etch, and metal deposition techniques.

Furthermore, such components may include any suitable materials. For example, gate dielectric 223 may be silicon oxide, aluminum oxide, or a high-k dielectric, such as hafnium oxide. For example, gate dielectric 223 may include elements such as hafnium, silicon, oxygen, titanium, tantalum, lanthanum, aluminum, zirconium, barium, strontium, yttrium, lead, scandium, niobium, or zinc. Gate electrodes 222 may include any suitable work function metal for gate control of form PMOS transistor 292 and NMOS transistor 291 such as tantalum, titanium, aluminum, ruthenium, or alloys of such materials. Source and drain contacts 221 and gate contact 219 may include any suitable conductive contact materials such as tungsten, copper, cobalt, aluminum, or the like.

As discussed, the alternative processing of PMOS transistor 292 and NMOS transistor 291 provides a thickness transition 211 between source and drain semiconductor 216 (e.g., n-type source and drain semiconductor) and source and drain semiconductor 218 (e.g., p-type source and drain semiconductor). In examples where edges of first mask 209 and second mask 213 align, a single thickness transition 211 is provided. When such first and second masks 209, 213 do not align, a double thickness transition is provided between source and drain semiconductor 216 and source and drain semiconductor 218 as discussed further herein below.

In the example, of FIG. 2J, integrated circuit structure 295 includes source or drain semiconductor 218 of a conductivity type (e.g., n-type) coupled to a number of channel layers 204 of gate-all-around transistor 291 and source or drain semiconductor 216 of another conductivity type (e.g., p-type) coupled to a number channel layers 204 of gate-all-around transistor 292 such that source or drain semiconductors 218, 216 are laterally adjacent one another (e.g., coplanar in the x-y plane). As used herein, the term lateral indicates substantially in line along a plane of a device such that the plane of the device is orthogonal to a build up layer of the device. The term adjacent indicates there is no like component between the adjacent components. Furthermore, dielectric material layer 208 extends between source or drain semiconductors 218, 216 such that dielectric material layer 208 is over isolation material 201 between gate-all-around transistors 291, 292.

As shown, dielectric material layer 208 has a thickness t1 at position p2 adjacent source or drain semiconductor 218 and a thickness t2, less than thickness t1, at a position p3 between position p2 and source or drain semiconductor 216. As shown, positions p2, p3 are on opposite sides of a position p1 defined at thickness transition 211. The first and second thicknesses t1, t2 may be any suitable thicknesses. In some embodiments, thickness t1 is in the range of 5 nm to 20 nm. In some embodiments, thickness t1 is in the range of 8 nm to 15 nm. In some embodiments, thickness t1 is in the range of 4 nm to 8 nm. In some embodiments, thickness t2 is in the range of 10 nm to 40 nm. In some embodiments, thickness t2 is in the range of 15 nm to 30 nm. In some embodiments, thickness t2 is in the range of 8 nm to 15 nm. Other thicknesses may be deployed. In some embodiments, a ratio of thickness t2 to t1 is not more than one-half (i.e., thickness t2 is not more than half of thickness t1). In some embodiments, ratio of thickness t2 to t1 is in the range of 0.25 to 0.75. In some embodiments, ratio of thickness t2 to t1 is in the range of 0.1 to 0.5. In some embodiments, ratio of thickness t2 to t1 is in the range of 0.4 to 0.9. Other ratios may be used.

As discussed, in examples where edges of first mask 209 and second mask 213 align at the position of thickness transition 211, a single thickness transition 211 is provided. When such first and second masks 209, 213 do not align, a double thickness transition is provided between source and drain semiconductor 216 and source and drain semiconductor 218.

FIG. 2K illustrates an example integrated circuit structure 296 similar to integrated circuit structure 290 fabricated with an edge 224 of second mask 213 misaligned with and overlapping thickness transition 211. As shown, at operation 106 (refer to FIG. 2F), when second mask 213 has an edge 224 that is misaligned with and overlaps thickness transition 211 (and therefore is misaligned with an opposing edge of first mask 209), an island 225 of dielectric material layer 208 is formed such that one side of island 225 is defined by thickness transition 211 at position p1 (which is aligned with first mask 209) and a thickness transition at position p4 (which is aligned with edge 224 of second mask 213 when there is an overlap).

In such examples, island 225 has a thickness t1 (i.e., between position p4 and position p1). Between position p4 and source and drain semiconductor 218, dielectric material layer 208 has a thickness less than thickness t1 and, between position p1 and source and drain semiconductor 216, dielectric material layer 208 has a thickness less than thickness t1. As illustrated, in some embodiments, both such thicknesses that are less than thickness t1 may be the same: thickness t2. In other embodiments, the thicknesses may be different. In some embodiments, one of the thicknesses may be zero. Notably, island 225 is not subject to any etch processing while a first region between source and drain semiconductor 218 and position p4 and a second region between position p1 and source and drain semiconductor 216 are subject to differing etch processing operations. Such thicknesses t1 and t2 (or alterative thickness if two thickness are present) may be any thicknesses discussed herein. Furthermore, the distance between positions p1 and p4 may be any suitable distance extending between source and drain semiconductors 218, 216 (i.e., extending in the x-direction). In some embodiments, positions p1 and p4 are not more than 15 nm apart in a direction extending between source and drain semiconductors 218, 216. In some embodiments, positions p1 and p4 are not more than 10 nm apart in a direction extending between source and drain semiconductors 218, 216. In some embodiments, positions p1 and p4 are not more than 5 nm apart in a direction extending between source and drain semiconductors 218, 216. In some embodiments, positions p1 and p4 are in the range of 2 to 10 nm apart in a direction extending between source and drain semiconductors 218, 216.

FIG. 2L illustrates an example integrated circuit structure 297 similar to integrated circuit structure 290 fabricated with edge 224 of second mask 213 misaligned with thickness transition 211 such that a gap is provided between edge 224 and thickness transition 211. As shown, at operation 106 (refer to FIG. 2F), when second mask 213 has edge 224 misaligned with and providing a gap between thickness transition 211 (and therefore is misaligned with an opposing edge of first mask 209), an indentation 226 (or notch) of dielectric material layer 208 is formed such that one side of indentation 226 is defined by thickness transition 211 at position p1 (which is aligned with first mask 209) and a thickness transition at position p4 (which is aligned with edge 224 of second mask 213 when there is a gap).

In such examples, indentation 226 has a thickness t2 (i.e., between position p1 and position p5). Between position p5 and source and drain semiconductor 216, dielectric material layer 208 has a thickness greater than thickness t2 and, between position p1 and source and drain semiconductor 218, dielectric material layer 208 has a thickness greater than thickness t2. As illustrated, in some embodiments, both such thicknesses that are greater than thickness t2 may be the same: thickness t1. In other embodiments, the thicknesses may be different. For example, indentation 226 is subject to two etch processing operations while a first region between source and drain semiconductor 218 and position p1 and a second region between position p5 and source and drain semiconductor 216 are subject to separate individual etch processing operations. Such thicknesses t2 and t1 (or alterative thickness if two thickness are present) may be any thicknesses discussed herein. Furthermore, the distance between positions p1 and p5 may be any suitable distance extending between source and drain semiconductors 218, 216 (i.e., extending in the x-direction). In some embodiments, positions p1 and p5 are not more than 15 nm apart in a direction extending between source and drain semiconductors 218, 216. In some embodiments, positions p1 and p5 are not more than 10 nm apart in a direction extending between source and drain semiconductors 218, 216. In some embodiments, positions p1 and p5 are not more than 5 nm apart in a direction extending between source and drain semiconductors 218, 216. In some embodiments, positions p1 and p5 are in the range of 2 to 10 nm apart in a direction extending between source and drain semiconductors 218, 216.

It is noted that integrated circuit structures 296, 297 may continue processing as discussed with respect to operation 110 and FIG. 2J to form gate-all-around transistor structures in analogy to gate-all-around transistors 291, 292.

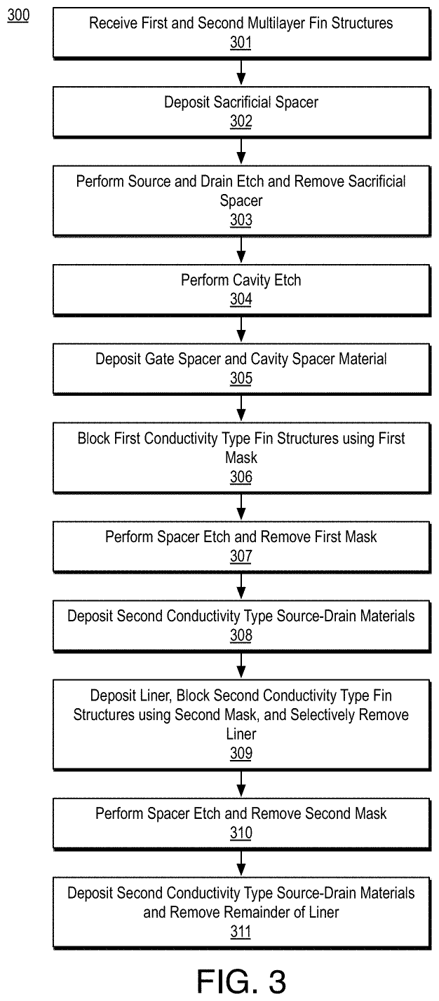

FIG. 3 illustrates a flow diagram illustrating another example process 300 for fabricating integrated circuit structures using a single lithographic patterning process for forming cavity spacers and source and drain materials in gate-all-around transistors of each conductivity type, arranged in accordance with at least some implementations of the present disclosure. For example, process 300 may be implemented to fabricate integrated circuit structure 495, or any other integrated circuit structures discussed herein. In the illustrated embodiment, process 100 includes one or more operations as illustrated by operations 301-311. However, embodiments herein may include additional operations, certain operations being omitted, or operations being performed out of the order provided. For example, process 300 may differ from process 100 in the manner in which the cavity spacers of the GAA transistors are formed.

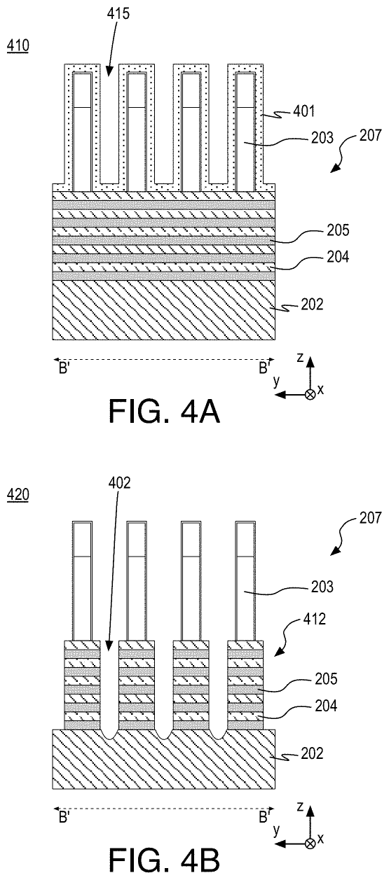

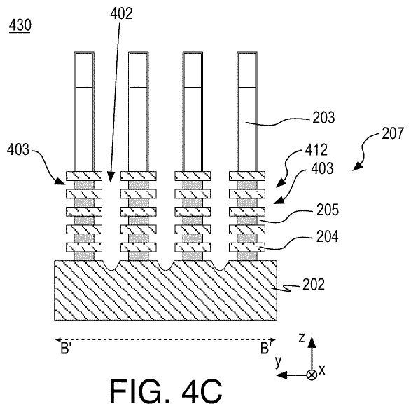

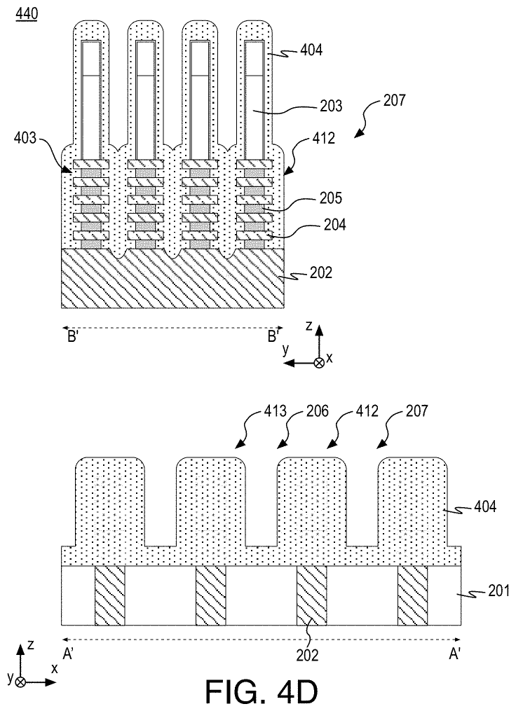

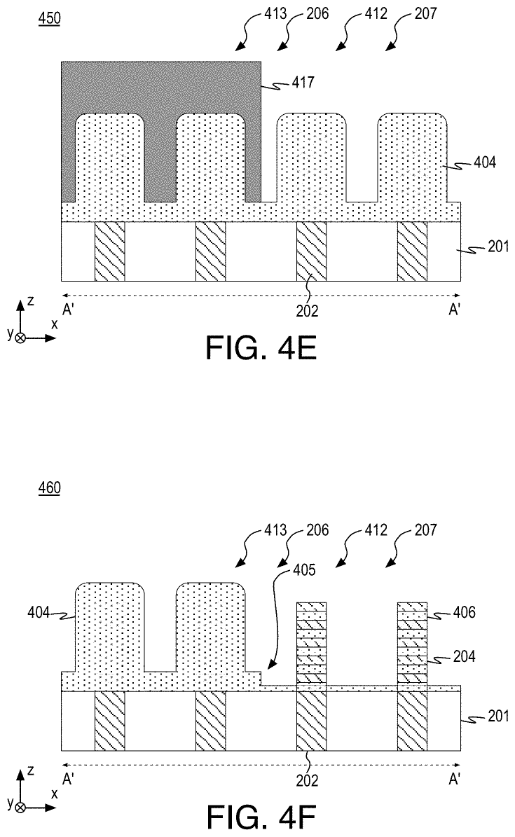

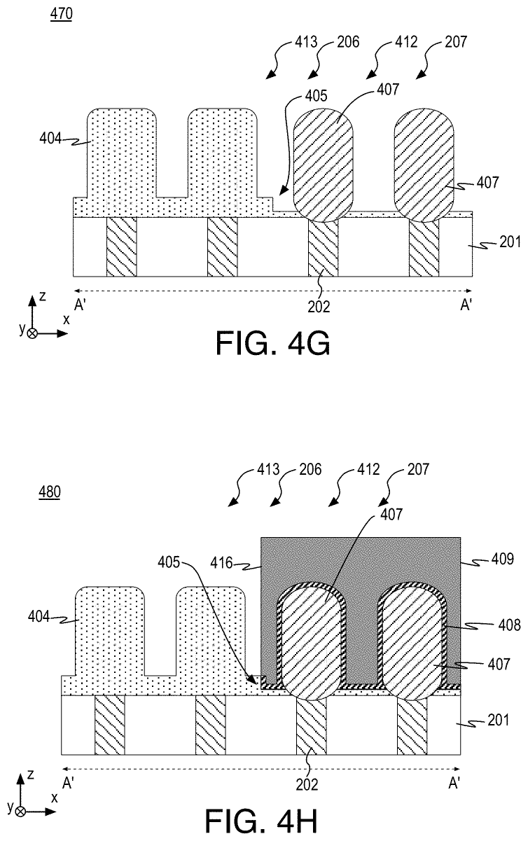

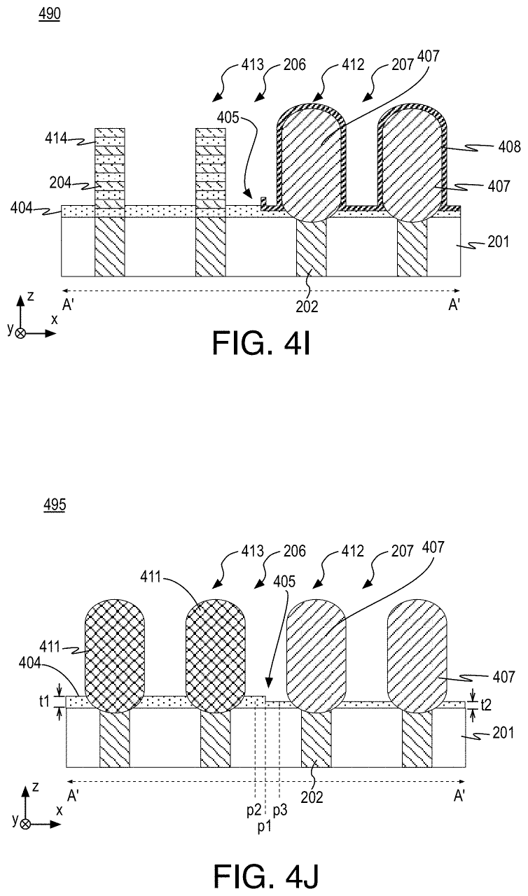

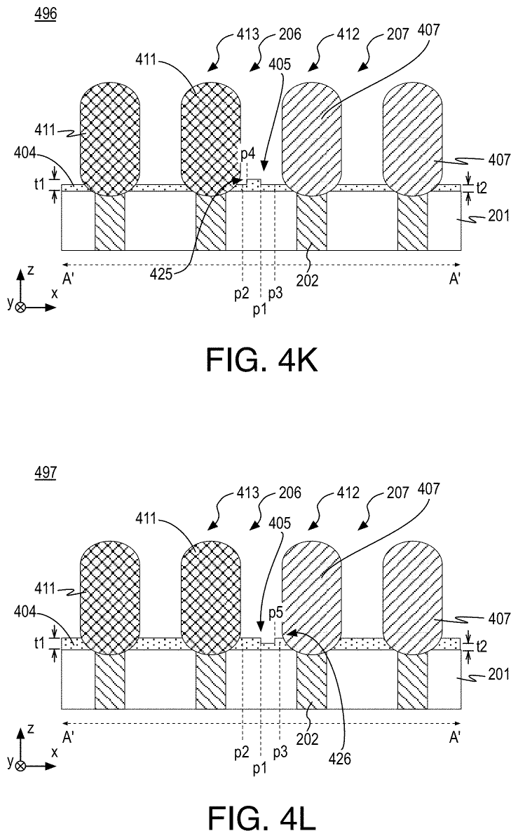

FIGS. 4A, 4B, 4C, 4D, 4E, 4F, 4G, 4H, 4I, 4J, 4K and 4L illustrate selected views of example integrated circuit structures as particular fabrication operations of process 300 are performed, arranged in accordance with at least some implementations of the present disclosure. In particular, reference will be made to FIGS. 4A, 4B, 4C, 4D, 4E, 4F, 4G, 4H, 4I, 4J, 4K and 4L in the context of process 300.

Process 300 begins at operation 301, where a number of multilayer fin structures over a substrate are received for processing. For example, any number of fin structures may be formed using known techniques on or over a substrate. In some embodiments, a multilayer stack of alternating first and second materials are bulk deposited over a substrate and patterned to form the multilayer fin structures. For example, the multilayer fin structures may include a subfin adjacent isolation materials and alternating first and second materials over the subfin and extending above the isolation materials. In some embodiments, the first material is the material chosen to be the channel material of the transistors and the second material is a sacrificial material to be removed and replaced by gate dielectric and gate metal.

Returning to FIG. 3, processing continues at operation 302, where a conformal sacrificial spacer is formed over the multilayer fin structures and the substrate. The conformal sacrificial spacer may be formed using any suitable technique or techniques such as CVD, PVD, ALD, or similar techniques. The conformal sacrificial spacer is to be used as a pattern for etching source and drain regions.

Referring now to FIG. 4A, an example integrated circuit structure 410 (e.g., IC structure work piece) is illustrated in a cross sectional view B′-B′ similar to the view B-B provided in illustrated in the top down view of FIG. 2A. For example, view B′-B′ is the same view taken along a fin structure inclusive of additional sacrificial gates 203 over and along multilayer fin structure 207. A GAA transistor of a first type (i.e., NMOS) is to be formed using multilayer fin structure 206 (refer to FIG. 2A) and a GAA transistor of a second type (i.e., PMOS) is to be formed using multilayer fin structure 207.

With reference to FIG. 4A, integrated circuit structure 410 includes multilayer fin structures, 206, 207 including subfins 202 that are isolated by isolation materials 201. Multilayer material stacks of channel semiconductor layers 204 and sacrificial material layers 205 extend above subfins 202. For example, channel semiconductor layers 204 are to remain as the channel layers of eventual GAA transistors while sacrificial material layers 205 will be removed and replaced by gate structures. Furthermore, prior to formation of the gate structures, sacrificial material layers 205 are recessed to form cavity spacers such that eventual source and drain materials are isolated from the gate contacts of the gate structures. Multilayer fin structures 206, 207 are over a substrate (not shown) and subfins 202 may be continuous with the substrate material of the substrate. The substrate may include any suitable material or materials discussed herein above. Channel semiconductor layers 204 may include any number of channel semiconductors, ribbons, or layers over the substrate such as three, four, five, or more layers. Channel semiconductor layers 204 are separated by sacrificial material layers 205, which will later be removed and replaced by one or more gate structures inclusive of, for example, gate dielectric materials and gate electrode materials. In some embodiments, channel semiconductor layers 204 include silicon (e.g., monocrystalline silicon, Si) and sacrificial material layers 205 include silicon and germanium (e.g., silicon germanium, SiGe).

As shown, a conformal layer 401 is formed over multilayer fin structures 206, 207 and sacrificial gates 203 (as well as isolation material 201 and the substrate). Conformal layer 401 may be characterized as a sacrificial spacer and may be used to provide patterning for source and drain regions 231, 233, 234, 236. Conformal layer 401 may be deposited using any suitable technique or techniques such as CVD, PVD, ALD, or similar techniques to any suitable thickness such as a thickness in the range of 2 to 30 nm. Conformal layer 401 may include any suitable materials such as dielectric oxides (e.g., silicon oxide, silicon oxynitride, silicon oxycarbide, etc.), metal oxides (e.g., aluminum oxide), or the like. Conformal layer 401, by coating sacrificial gates 203, provides a mask with openings 415 providing locations to perform source and drain etch in source and drain regions 231, 233, 234, 236.

Returning to FIG. 3, processing continues at operation 303, where a source and drain etch are performed to remove portion of multilayer fin structures in source and drain regions 231, 233, 234, 236 and the remaining sacrificial conformal layer is removed. For example, the removed portions of multilayer fin structures are removed to provide locations for source and drain semiconductors of the GAA transistors. The source and drain etch may be performed using any suitable technique or techniques. In some embodiments, the source and drain etch is performed using anisotropic etch techniques selective to the materials of the multilayer fin structures (e.g., Si and SiGe). Such etch processing removes the multilayer fin structures in the source and drain regions (e.g., source and drain regions 231, 233, 234, 236; refer to FIG. 2a) and exposes the channel semiconductor material layers and sacrificial layers via those removed regions. The remaining channel semiconductor material layers and sacrificial layers may be characterized as multilayer channel structures as they include the channel materials of the eventual GAA transistors. Notably, the multilayer fin structures in the source and drain regions are removed for both multilayer fin structures 206, 207 simultaneously. After the source and drain etch, the remainder of sacrificial spacer layer deposited at operation 302 is removed using, for example, wet etch techniques.

FIG. 4B illustrates an example integrated circuit structure 420 similar to integrated circuit structure 410 after source and drain etch and removal of conformal layer 401. As shown, the source and drain etch of operation 303 removes source and drain regions 402 of multilayer fin structures 206, 207 to provide multilayer channel structures 412. Each of multilayer channel structures 412 includes alternating material layers of channel semiconductor layers 204 and sacrificial material layers 205. In the view of B′-B′ (analogous to view B-B), a number of gate regions 235 (which may also be characterized as channel regions) are illustrated and the multilayer materials have been removed from the source and drain regions. With reference to FIG. 2A, the same holds for multilayer fin structure 206 (and any other fin structures extending in the y-direction and parallel to multilayer fin structures 206, 207. Notably, the multilayer channel structures remain in gate regions 232 while the multilayer material stack has been removed for source and drain regions 231, 233.

Returning to FIG. 3, processing continues at operation 304, where a cavity etch is performed to etch back the sacrificial material layers of the multilayer channel structures. As discussed, in forming the source and drain semiconductors on the channel semiconductors, the source and drain semiconductors must be isolated from the gate metal or electrode eventually formed in place of the sacrificial material layers of the multilayer channel structures. Such isolation is provided by cavity spacers formed via operations 304, 305. Using the techniques of process 300, the cavity spacers are not repeatedly exposed and eroded. Thereby, cavity spacers having improved integrity are provided in the GAA transistors for improved isolation, reduced leakage, and other improved transistor characteristics. The cavity etch may be performed using any suitable technique or techniques such as timed isotopic etch techniques selective to the sacrificial materials of the multilayer structures. For example, an isotropic SiGe etch may be deployed. The resultant cavities or recesses adjacent the sacrificial materials of the multilayer fin structures may then be filled with cavity spacer materials.

FIG. 4C illustrates an example integrated circuit structure 430 similar to integrated circuit structure 430 after a cavity spacer etch has provided recesses 403 in sacrificial material layers 205 relative to channel semiconductor layers 204. For example, sacrificial material layers 205 are recessed using a selective recess etch (e.g., selective isotropic etch) such that channel semiconductor layers 204 are substantially unaffected. Recesses 403 provide locations for cavity spacer material to isolate source and drain semiconductor from gate metal as discussed herein.

Returning to FIG. 3, processing continues at operation 305, where a gate spacer and cavity spacer material are deposited within the source and drain regions and over the sacrificial gates. The gate spacer and cavity spacer material may be deposited using any suitable technique or techniques such as chemical vapor deposition (CVD), physical vapor deposition (PVD), atomic layer deposition (ALD), or similar techniques. The gate spacer and cavity spacer material may include any material may include any suitable dielectric material such as a low-k dielectric material.

FIG. 4D illustrates an example integrated circuit structure 440 similar to integrated circuit structure 430 after deposition of gate spacer and cavity spacer dielectric material layer 404. FIG. 4D further provides a cross sectional view A′-A′ similar to the view A-A provided in illustrated in the top down view of FIG. 2A. For example, view A′-A′ is similar to the view taken across multilayer fin structures (or multilayer channel structures) in source and drain regions thereof, such as source and drain regions 233, 236. In the view of A′-A′, additional multilayer fin structures are illustrated inclusive of one additional fin structure in the negative x-direction relative to multilayer fin structure 206 that is to have the same conductivity type (e.g., NMOS) as multilayer fin structure 206, and another additional fin structure in the positive x-direction relative to multilayer fin structure 207 that is to have the same conductivity type (e.g., NMOS) as multilayer fin structure 207. As shown, multilayer channel structures 413 were formed from multilayer fin structures 206 as discussed with respect to operations 302-304.

As shown, dielectric material layer 404 fills source and drain regions 402 and provides a conformal layer over sacrificial gates 203. Notably, in GAA transistors formed according to process 300, cavity spacers and gate spacers are formed of the same material(s). Dielectric material layer 404 may include any suitable dielectric material. In some embodiments, dielectric material layer 404 is a low-k dielectric material. In some embodiments, dielectric material layer 404 includes one or more of silicon, oxygen, carbon and nitrogen. In some embodiments, dielectric material layer 404 is a material including silicon and oxygen (e.g., silicon oxide, SiO₂). In addition to silicon and oxygen, dielectric material layer 404 may include nitrogen (e.g., silicon oxynitride) or carbon (e.g., silicon oxycarbide).

Returning to FIG. 3, processing continues at operation 306, where a first mask is formed to selectively expose first multilayer fin structures (PMOS transistors or NMOS transistors) and cover second multilayer fin structures (the other of NMOS or PMOS transistors). In the illustrated example, NMOS transistor multilayer fin structures are first blocked or covered; however, the processing order may be reversed. The first mask may be formed using any suitable technique or techniques such as photolithography techniques (e.g., resist deposition, expose, develop) and the first mask may be any suitable material or materials such as resist materials, hard mask materials, etc.

FIG. 4E illustrates an example integrated circuit structure 450 similar to integrated circuit structure 440 after formation of first mask 417 to block multilayer channel structures 413 (or multilayer fin structures 206) and to expose multilayer channel structures 412 (or multilayer fin structures 207). As shown, multilayer channel structures 413 are under first mask 417 and are therefore blocked by first mask 417 while multilayer channel structures 412 are not under first mask 417 and are therefore exposed by first mask 417 (although a portion of dielectric material layer 404 is over multilayer channel structures 412). As discussed, first mask 417 may be formed using photolithography techniques and may include any suitable material or materials to protect regions under first mask 417 during subsequent processing. Furthermore, first mask 417 may have any thickness to properly mask such regions.

Returning to FIG. 3, processing continues at operation 307, where a spacer etch is performed to remove portions of the gate spacer and cavity spacer dielectric material, and the first mask is removed. In particular, the gate spacer and cavity spacer dielectric material is substantially removed from the source and drain regions while leaving cavity spacers of the gate spacer and cavity spacer dielectric material in the recesses discussed with respect to FIG. 4C. Furthermore, the spacer etch may leave gate spacer material on the sidewalls of sacrificial gates 203. The spacer etch may be performed using any suitable technique or techniques such as anisotropic etch techniques. The first mask is then removed using any suitable technique or techniques such as ash processing techniques.

FIG. 4F illustrates an example integrated circuit structure 460 similar to integrated circuit structure 450 after spacer etch is performed to remove portions of dielectric material layer 404, and after removal of first mask 417. Such processing exposes the source and drain regions for GAA transistors of a first conductivity type (e.g., PMOS). As shown, removal of portions of dielectric material layer 404 leaves a thickness transition 405 analogous to thickness transition 211. As shown, a thinner portion of dielectric material layer 404 may be provided over isolation material 201 adjacent multilayer channel structures 412 (or multilayer fin structures 207). The remaining dielectric material layer 404 between multilayer channel structures 413 (or multilayer fin structures 206) and multilayer channel structures 412 (or multilayer fin structures 207) may have any thickness characteristics discussed herein with respect to dielectric material layer 208.

As shown, the discussed spacer etch processing advantageously removes dielectric material layer 404 in source and drain regions to expose channel semiconductor layers 204 and to leave cavity spacers 406 in recesses 403 (refer to FIG. 4C). In some embodiments, cavity spacers 406 include a low-k dielectric material. In some embodiments, cavity spacers 406 include one or more of silicon, oxygen, carbon and nitrogen. In some embodiments, cavity spacers 406 deploy a material including silicon and oxygen (e.g., silicon oxide, SiO₂). In addition to silicon and oxygen, dielectric material layer 404 may include nitrogen (e.g., silicon oxynitride) or carbon (e.g., silicon oxycarbide).

Multilayer channel structures 412 (or multilayer fin structure 207) are then prepared for application of a source and drain material for an eventual GAA semiconductor device. Notably, channel semiconductor layers 204 are exposed in source and drain regions 234, 236 while sacrificial material layers 205 are covered by cavity spacers 406.

Returning to FIG. 3, processing continues at operation 308, where source and drain semiconductor materials suitable for the conductivity type of the GAA transistor being formed are deposited (e.g., epitaxially grown). As discussed, the resultant structure from operation 307 provides transistor channel materials exposed for only one conductivity type (e.g., PMOS) devices to be formed. Epitaxial source and drain semiconductor materials may then be selectively formed on the exposed transistor channel materials (e.g., channel silicon). Such epitaxial growth techniques may be performed using any suitable technique or techniques such as vapor phase epitaxy, molecular beam epitaxy techniques, or the like. Such epitaxial growth is selective to exposed crystal surfaces of the channel semiconductor and grows substantially crystalline source and drain materials that are epitaxial to (e.g., share a crystal orientation with) the channel semiconductor.

FIG. 4G illustrates an example integrated circuit structure 470 similar to integrated circuit structure 460 after the formation of source and drain semiconductor 407 on the exposed channel semiconductor layers 204. Source and drain semiconductor 407 may be formed using any suitable technique or techniques such as vapor phase epitaxy techniques, molecular beam epitaxy techniques, or other epitaxial growth techniques. As shown, source and drain semiconductor 407 grows epitaxially from exposed channel semiconductor layers 204. Source and drain semiconductor 407 may include faceting and growth structures and characteristics as known in the art. Source and drain semiconductor 407 may include any suitable material or materials for the conductivity type of GAA being formed. In some embodiments, for NMOS GAA transistors, source and drain semiconductor 407 is epitaxial silicon doped with n-type dopants inclusive of phosphorous, arsenic, antimony, or others. In some embodiments, for PMOS GAA transistors, source and drain semiconductor 407 is epitaxial silicon germanium doped with p-type dopants inclusive of boron, aluminum, gallium, indium, or others. In the illustrated example, source and drain semiconductor 407 is p-type; however, as discussed the processing order of NMOS and PMOS GAA transistors may be reversed.

Returning to FIG. 3, processing continues at operation 309, where a protective liner is formed on the resultant source and drain semiconductor materials, a second mask is formed to selectively expose second multilayer fin structures (i.e., for NMOS transistors if PMOS transistors have been processed or vice versa) and cover first multilayer fin structures (the other of NMOS or PMOS transistors), and exposed portions of the liner material are removed. As discussed, either NMOS or PMOS GAA transistors may be processed first. Herein, the convention that PMOS transistors are processed first is maintained for the sake of clarity. The protective liner may be formed using any suitable technique or techniques such as CVD, PVD, ALD, or similar techniques. The second mask may then be formed using any suitable technique or techniques such as photolithography techniques and the second mask may be any suitable material or materials such as resist materials, hard mask materials, etc. The exposed liner material may then be removed using any suitable technique or techniques such as wet etch techniques.

FIG. 4H illustrates an example integrated circuit structure 480 similar to integrated circuit structure 470 after the formation of liner material 408, the formation of second mask 409, and the removal of exposed portions of liner material 408. For example, a conformal liner material 408 may be formed over the exposed surfaces of source and drain semiconductor 407 and dielectric material layer 404. Liner material 408 may be formed using any suitable technique or techniques such as CVD, PVD, ALD, or similar techniques to any suitable thickness such as a thickness in the range of 2 to 30 nm. Liner material 408 may be any suitable material that provides protection for source and drain semiconductor 407 and blocks epitaxial growth thereon. In some embodiments, liner material 408 is a dielectric oxide (e.g., silicon oxide, silicon oxynitride, silicon oxycarbide, etc.). In some embodiments, liner material 408 is a metal oxide (e.g., aluminum oxide). For example, liner material 408 may include oxygen and one or more of silicon, nitrogen, or aluminum.

Second mask 409 is then formed such that multilayer channel structures 412 (or multilayer fin structures 207) are under second mask 409 and are therefore blocked by second mask 409 while multilayer channel structures 413 (or multilayer fin structures 206) are not under second mask 409 and are therefore exposed by second mask 409 (although a portion of dielectric material layer 404 and a portion of liner material 408 are thereon). As discussed, second mask 409 may be formed using photolithography techniques and may include any suitable material or materials to protect regions under second mask 409 during subsequent processing. Furthermore, second mask 409 may have any thickness to properly mask such regions. In the example of FIG. 4H, an edge 416 of second mask 409 is aligned with thickness transition 405. However, as discussed, any combination of first to second mask alignment and corresponding thicknesses and characteristics discussed with respect to dielectric material layer 208 may be formed in dielectric material layer 404. Subsequent to the formation of second mask 409, exposed portions of liner material 408 are removed, leaving a liner edge substantially at thickness transition 405. Exposed portions of liner material 408 may be removed using any suitable technique or techniques such as wet etch techniques.

Returning to FIG. 3, processing continues at operation 310, where a spacer etch is performed to remove portions of the gate spacer and cavity spacer dielectric material, and the second mask is removed. In operation 310, the gate spacer and cavity spacer dielectric material is substantially removed from the source and drain regions while leaving cavity spacers of the gate spacer and cavity spacer dielectric material in the recesses discussed with respect to FIG. 4C. Furthermore, the spacer etch may leave gate spacer material on the sidewalls of sacrificial gates 203. The spacer etch may be performed using any suitable technique or techniques such as anisotropic etch techniques. The second mask is then removed using any suitable technique or techniques such as ash processing techniques.

FIG. 4I illustrates an example integrated circuit structure 490 similar to integrated circuit structure 480 after spacer etch is performed to remove portions of dielectric material layer 404, and after removal of second mask 409. Such processing exposes the source and drain regions for GAA transistors of a second conductivity type (e.g., NMOS). In the illustrated example, the removal dielectric material layer 404 does not remove as much material from over isolation material 201 as discussed with respect to the removal operation of FIG. 4F such that thickness transition 405 is maintained with a thicker portion of dielectric material layer 404 adjacent multilayer fin structure 206 and thinner portion of dielectric material layer 404 adjacent source and drain semiconductor 407 and multilayer fin structure 207. In other embodiments, the removal dielectric material layer 404 may exceed that of the previous removal such that a thinner portion of dielectric material layer 404 is adjacent multilayer fin structure 206 and thicker portion of dielectric material layer 404 is adjacent source and drain semiconductor 407 and multilayer fin structure 207, such that the location of thickness transition 405 is maintained.

The spacer etch processing advantageously removes dielectric material layer 404 in source and drain regions to expose channel semiconductor layers 204 and to leave cavity spacers 414 in recesses analogous to recesses 403 (refer to FIG. 4C). Cavity spacers 414 may include any materials or materials discussed with respect to dielectric material layer 404 and cavity spacers 406 such as low-k dielectric materials. Multilayer channel structures 413 (or multilayer fin structures 206) are then prepared for application of a source and drain material for an eventual GAA semiconductor device. Notably, channel semiconductor layers 204 are exposed in source and drain regions 234, 236 while sacrificial material layers 205 are covered by cavity spacers 406.

Returning to FIG. 3, processing continues at operation 311, where source and drain semiconductor materials suitable for the conductivity type of the GAA transistor being formed are deposited (e.g., epitaxially grown) and the remainder of the liner material is removed. As discussed, the resultant structure from operation 310 provides transistor channel materials exposed for only one conductivity type (e.g., PMOS) transistors to be formed. Epitaxial source and drain semiconductor materials may then be selectively formed on the exposed transistor channel materials (e.g., channel silicon) such that they have a different conductivity type wert those deposited at operation 308. Such epitaxial growth techniques may be performed using any suitable technique or techniques such as vapor phase epitaxy, molecular beam epitaxy techniques, or the like. The remainder of the liner material may be removed using any suitable technique or techniques such as wet etch techniques.

FIG. 4J illustrates an example integrated circuit structure 495 similar to integrated circuit structure 490 after the formation of source and drain semiconductor 411 on the exposed channel semiconductor layers 204 and removal of liner material 408. Source and drain semiconductor 411 may be formed using any suitable technique or techniques such as vapor phase epitaxy techniques, molecular beam epitaxy techniques, or other epitaxial growth techniques. Source and drain semiconductor 411 grows epitaxially from exposed channel semiconductor layers 204, and source and drain semiconductor 407 may include faceting and epitaxial growth structures and characteristics. Source and drain semiconductor 411 may include any suitable material or materials for the conductivity type of GAA being formed. In some embodiments, for NMOS GAA transistors, source and drain semiconductor 411 is epitaxial silicon doped with n-type dopants inclusive of phosphorous, arsenic, antimony, or others. In some embodiments, for PMOS GAA transistors, source and drain semiconductor 411 is epitaxial silicon germanium doped with p-type dopants inclusive of boron, aluminum, gallium, indium, or others. In the illustrated example, source and drain semiconductor 411 is p-type; however, as discussed the processing order of NMOS and PMOS GAA transistors may be reversed. The remainder of liner material 408 may be removed using wet etch techniques.

Processing continues with transistor processing being completed as discussed with respect to operation 110 of process 100. Such processing may be performed using any suitable technique or techniques. In some embodiments, the sacrificial layers adjacent the channel semiconductor and the dummy gate materials may be replaced with gate structures using any suitable technique or techniques known in the art. For example, the sacrificial layers may be selectively etched and the requisite structures may be formed via deposition and optional patterning techniques. Furthermore, source and drain semiconductors and gate electrodes may be contacted by metal contacts using any suitable technique or techniques such as patterning and metal deposition processing known in the art. Such gate dielectrics, gate electrodes, source and drain contacts, and gate contacts may have any characteristics discussed with respect to FIG. 2J.

As discussed, the alternative processing of PMOS transistor and NMOS transistor types provides thickness transition 405 between source and drain semiconductor 407 (e.g., n-type source and drain semiconductor) and source and drain semiconductor 411 (e.g., p-type source and drain semiconductor). In examples where edges of first mask 417 and second mask 409 align, a single thickness transition 405 is provided. When such first and second masks 417, 409 do not align, a double thickness transition is provided between source and drain semiconductor 407 and source and drain semiconductor 411.

In the example, of FIG. 4J, integrated circuit structure 495 includes source or drain semiconductor 411 of a conductivity type (e.g., n-type) coupled to a number of channel layers 204 of a gate-all-around transistor and source or drain semiconductor 407 of another conductivity type (e.g., p-type) coupled to a number channel layers 204 of another gate-all-around transistor such that source or drain semiconductors 411, 407 are laterally adjacent one another (e.g., coplanar in the x-y plane). Furthermore, dielectric material layer 404 extends between source or drain semiconductors 411, 407 such that dielectric material layer 404 is over isolation material 201 between the corresponding gate-all-around transistors.

As shown, dielectric material layer 404 has a thickness t1 at position p2 adjacent source or drain semiconductor 411 and a thickness t2, less than thickness t1, at a position p3 between position p2 and source or drain semiconductor 407. As shown, positions p2, p3 are on opposite sides of a position p1 defined at thickness transition 211. The first and second thicknesses t1, t2 may be any suitable thicknesses. In some embodiments, thickness t1 is in the range of 5 nm to 20 nm. In some embodiments, thickness t1 is in the range of 8 nm to 15 nm. In some embodiments, thickness t1 is in the range of 4 nm to 8 nm. In some embodiments, thickness t2 is in the range of 10 nm to 40 nm. In some embodiments, thickness t2 is in the range of 15 nm to 30 nm. In some embodiments, thickness t2 is in the range of 8 nm to 15 nm. Other thicknesses may be deployed.

In some embodiments, a ratio of thickness t2 to t1 is not more than one-half (i.e., thickness t2 is not more than half of thickness t1). In some embodiments, ratio of thickness t2 to t1 is in the range of 0.25 to 0.75. In some embodiments, ratio of thickness t2 to t1 is in the range of 0.1 to 0.5. In some embodiments, ratio of thickness t2 to t1 is in the range of 0.4 to 0.9. Other ratios may be used.

As discussed, in examples where edges of first mask 417 and second mask 409 align at the position of thickness transition 405, a single thickness transition 405 is provided. When such first and second masks 417, 409 do not align, a double thickness transition is provided between source and drain semiconductor 407 and source and drain semiconductor 411.

FIG. 4K illustrates an example integrated circuit structure 496 similar to integrated circuit structure 495 fabricated with an edge of second mask 409 misaligned with and overlapping thickness transition 405 (refer to FIG. 2K for representation of overlapping misalignment). When second mask 409 has an edge that is misaligned with and overlaps thickness transition 405 (and therefore is misaligned with an opposing edge of first mask 417), an island 425 of dielectric material layer 404 is formed such that one side of island 425 is defined by thickness transition 405 at position p1 (which is aligned with first mask 417) and a thickness transition at position p4 (which is aligned with an edge of second mask 409 when there is an overlap).

In such examples, island 425 has a thickness t1 (i.e., between position p4 and position p1). Between position p4 and source and drain semiconductor 411, dielectric material layer 404 has a thickness less than thickness t1 and, between position p1 and source and drain semiconductor 407, dielectric material layer 404 has a thickness less than thickness t1. As illustrated, in some embodiments, both such thicknesses that are less than thickness t1 may be the same: thickness t2. In other embodiments, the thicknesses may be different. In some embodiments, one of the thicknesses may be zero. Notably, island 425 is not subject to any etch processing while a first region between source and drain semiconductor 411 and position p4 and a second region between position p1 and source and drain semiconductor 407 are subject to differing etch processing operations. Such thicknesses t1 and t2 (or alterative thickness if two thickness are present) may be any thicknesses discussed herein. Furthermore, the distance between positions p1 and p4 may be any suitable distance extending between source and drain semiconductors 411, 407 (i.e., extending in the x-direction). In some embodiments, positions p1 and p4 are not more than 15 nm apart in a direction extending between source and drain semiconductors 411, 407. In some embodiments, positions p1 and p4 are not more than 10 nm apart in a direction extending between source and drain semiconductors 411, 407. In some embodiments, positions p1 and p4 are not more than 5 nm apart in a direction extending between source and drain semiconductors 411, 407. In some embodiments, positions p1 and p4 are in the range of 2 to 10 nm apart in a direction extending between source and drain semiconductors 411, 407.

FIG. 4L illustrates an example integrated circuit structure 497 similar to integrated circuit structure 495 fabricated with an edge of second mask 409 misaligned with thickness transition 405 such that a gap is provided between the edge and thickness transition 405 (refer to FIG. 2L for representation of gap misalignment). When second mask 409 has an edge misaligned with and providing a gap between thickness transition 405 (and therefore is misaligned with an opposing edge of first mask 417), an indentation 426 (or notch) of dielectric material layer 404 is formed such that one side of indentation 426 is defined by thickness transition 405 at position p1 (which is aligned with first mask 417) and a thickness transition at position p5 (which is aligned with the edge of second mask 409 when there is a gap).

In such examples, indentation 426 has a thickness t2 (i.e., between position p1 and position p5). Between position p5 and source and drain semiconductor 407, dielectric material layer 404 has a thickness greater than thickness t2 and, between position p1 and source and drain semiconductor 411, dielectric material layer 404 has a thickness greater than thickness t2. As illustrated, in some embodiments, both such thicknesses that are greater than thickness t2 may be the same: thickness t1. In other embodiments, the thicknesses may be different. For example, indentation 426 is subject to two etch processing operations while a first region between source and drain semiconductor 411 and position p1 and a second region between position p5 and source and drain semiconductor 407 are subject to separate individual etch processing operations. Such thicknesses t2 and t1 (or alterative thickness if two thickness are present) may be any thicknesses discussed herein. Furthermore, the distance between positions p1 and p5 may be any suitable distance extending between source and drain semiconductors 411, 407 (i.e., extending in the x-direction). In some embodiments, positions p1 and p5 are not more than 15 nm apart in a direction extending between source and drain semiconductors 411, 407. In some embodiments, positions p1 and p5 are not more than 10 nm apart in a direction extending between source and drain semiconductors 411, 407. In some embodiments, positions p1 and p5 are not more than 5 nm apart in a direction extending between source and drain semiconductors 411, 407. In some embodiments, positions p1 and p5 are in the range of 2 to 10 nm apart in a direction extending between source and drain semiconductors 411, 407.

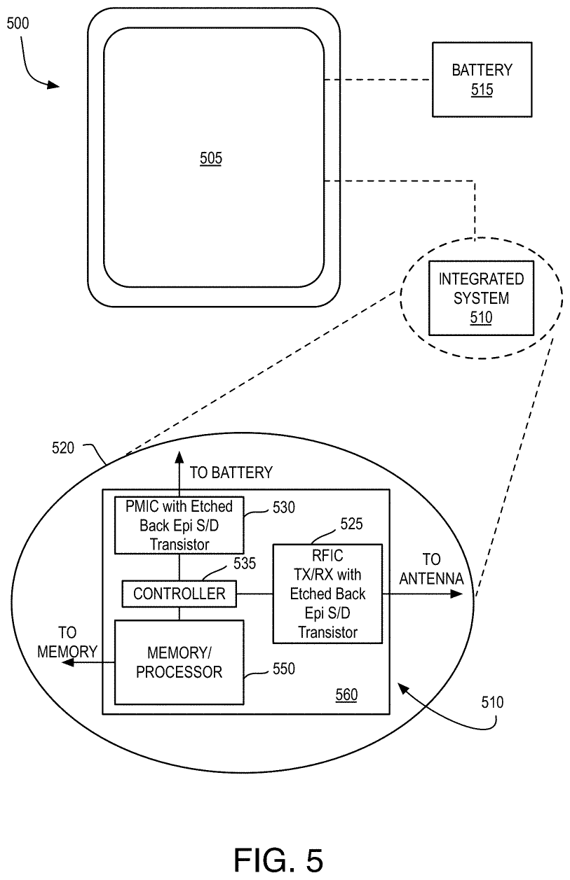

FIG. 5 is an illustrative diagram of a mobile computing platform 500 employing an integrated circuit device with gate-all-around transistors formed by combining source and drain etch, cavity spacer formation, and source and drain semiconductor growth, arranged in accordance with at least some implementations of the present disclosure. Any die or device having a transistor structure inclusive of any components, materials, or characteristics discussed herein may be implemented by any component of mobile computing platform 500. Mobile computing platform 500 may be any portable device configured for each of electronic data display, electronic data processing, wireless electronic data transmission, or the like. For example, mobile computing platform 500 may be any of a tablet, a smart phone, a netbook, a laptop computer, etc. and may include a display screen 505, which in the exemplary embodiment is a touchscreen (e.g., capacitive, inductive, resistive, etc. touchscreen), a chip-level (system on chip-SoC) or package-level integrated system 510, and a battery 515. Battery 515 may include any suitable device for providing electrical power such as a device consisting of one or more electrochemical cells and electrodes to couple to an outside device. Mobile computing platform 500 may further include a power supply to convert a source power from a source voltage to one or more voltages employed by other devices of mobile computing platform 500.

Integrated system 510 is further illustrated in the expanded view 520. In the exemplary embodiment, packaged device 550 (labeled “Memory/Processor” in FIG. 5) includes at least one memory chip (e.g., RAM), and/or at least one processor chip (e.g., a microprocessor, a multi-core microprocessor, or graphics processor, or the like). In an embodiment, the package device 550 is a microprocessor including an SRAM cache memory. As shown, device 550 may employ a die or device having any transistor structures and/or related characteristics discussed herein. Packaged device 550 may be further coupled to (e.g., communicatively coupled to) a board, a substrate, or an interposer 560 along with, one or more of a power management integrated circuit (PMIC) 530, RF (wireless) integrated circuit (RFIC) 525 including a wideband RF (wireless) transmitter and/or receiver (TX/RX) (e.g., including a digital baseband and an analog front end module further comprises a power amplifier on a transmit path and a low noise amplifier on a receive path), and a controller 535 thereof. In general, packaged device 550 may be also be coupled to (e.g., communicatively coupled to) display screen 505. As shown, one or both of PMIC 530 and/or RFIC 525 may employ a die or device having any transistor structures and/or related characteristics discussed herein.

Functionally, PMIC 530 may perform battery power regulation, DC-to-DC conversion, etc., and so has an input coupled to battery 515 and with an output providing a current supply to other functional modules. In an embodiment, PMIC 530 may perform high voltage operations. As further illustrated, in the exemplary embodiment, RFIC 525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. In alternative implementations, each of these board-level modules may be integrated onto separate ICs coupled to the package substrate of packaged device 550 or within a single IC (SoC) coupled to the package substrate of the packaged device 550.

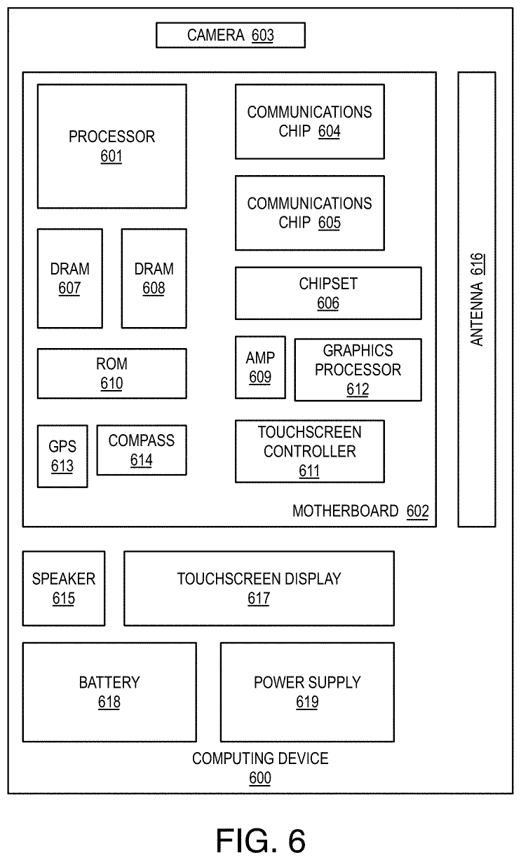

FIG. 6 is a functional block diagram of a computing device 600, arranged in accordance with at least some implementations of the present disclosure. Computing device 600 may be found inside platform 500, for example, and further includes a motherboard 602 hosting a number of components, such as but not limited to a processor 601 (e.g., an applications processor) and one or more communications chips 604, 605. Processor 601 may be physically and/or electrically coupled to motherboard 602. In some examples, processor 601 includes an integrated circuit die packaged within the processor 601. In general, the term “processor” may refer to any device or portion of a device that processes electronic data from registers and/or memory to transform that electronic data into other electronic data that may be stored in registers and/or memory. Any one or more device or component of computing device 600 may include a die or device having any integrated circuit gate-all-around transistor structures and/or related characteristics as discussed herein.

In various examples, one or more communication chips 604, 605 may also be physically and/or electrically coupled to the motherboard 602. In further implementations, communication chips 604 may be part of processor 601. Depending on its applications, computing device 600 may include other components that may or may not be physically and electrically coupled to motherboard 602. These other components may include, but are not limited to, volatile memory (e.g., DRAM) 607, 608, non-volatile memory (e.g., ROM) 610, a graphics processor 612, flash memory, global positioning system (GPS) device 613, compass 614, a chipset 606, an antenna 616, a power amplifier 609, a touchscreen controller 611, a touchscreen display 617, a speaker 615, a camera 603, a battery 618, and a power supply 619, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like.

Communication chips 604, 605 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 604, 605 may implement any of a number of wireless standards or protocols, including but not limited to those described elsewhere herein. As discussed, computing device 600 may include a plurality of communication chips 604, 605. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. Furthermore, power supply 619 may convert a source power from a source voltage to one or more voltages employed by other devices or components of computing device 600 (or mobile computing platform 500). In some embodiments, power supply 619 converts an AC power to DC power. In some embodiments, power supply 619 converts an DC power to DC power at one or more different (lower) voltages. In some embodiments, multiple power supplies are staged to convert from AC to DC and then from DC at a higher voltage to DC at a lower voltage as specified by components of computing device 600.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

The following embodiments pertain to further embodiments.

In one or more first embodiments, an integrated circuit device comprises a first source or drain semiconductor of a first conductivity type coupled to a plurality of first channel layers of a first gate-all-around transistor, a second source or drain semiconductor of a second conductivity type coupled to a plurality of second channel layers of a second gate-all-around transistor, the second source or drain laterally adjacent the first source or drain, and a dielectric layer extending between the first source or drain semiconductor and the second source or drain semiconductor, the dielectric material over an isolation material between the first and second gate-all-around transistors, the dielectric layer comprising a first thickness at a first position adjacent the first source or drain semiconductor and a second thickness, less than the first thickness, at a second position between the first position and the second source or drain semiconductor.

In one or more second embodiments, further to the first embodiment, the second thickness is not more than half the first thickness.

In one or more third embodiments, further to the first or second embodiments, the isolation material comprises silicon and oxygen, and the dielectric layer comprises silicon and at least one of oxygen, carbon, or nitrogen.

In one or more fourth embodiments, further to any of the first through third embodiments, the dielectric layer comprises a third thickness, greater than the second thickness, at a third position between the second position and the second source or drain.

In one or more fifth embodiments, further to any of the first through fourth embodiments, first position and the third position are not more than 10 nm apart in a direction extending between the first and second source or drain.

In one or more sixth embodiments, further to any of the first through fifth embodiments, the dielectric layer comprises a third thickness, less than the first thickness, at a third position between the first position and the first source or drain.

In one or more seventh embodiments, further to any of the first through sixth embodiments, first position and the third position are not more than 10 nm apart in a direction extending between the first and second source or drain.

In one or more eighth embodiments, further to any of the first through seventh embodiments, the dielectric layer comprises a same material as a gate spacer of the first and second gate-all-around transistors.

In one or more ninth embodiments, further to any of the first through eighth embodiments, the first and second gate-all-around transistors are over a substrate of a monolithic die, the integrated circuit device further comprising a power supply coupled to the monolithic die.

In one or more tenth embodiments, a system comprises a power supply and an integrated circuit die coupled to the power supply, the integrated circuit die comprising an integrated circuit device according to any of the first through ninth embodiments.

In one or more eleventh embodiments, a method of fabricating an integrated circuit structure comprises forming a first mask to selectively expose a first multilayer fin structure and cover a second multilayer fin structure, the first and second multilayer fin structures comprising alternating layers of first and second materials, removing a portion of the first multilayer fin adjacent a channel region thereof, recessing the first materials of the first multilayer fin and forming cavity spacers adjacent the recessed first materials, removing the first mask, epitaxially depositing a source or drain material comprising a first conductivity type on the second material of the first multilayer fin structure, and forming a second mask to selectively expose the second multilayer fin structure and mask the first multilayer fin structure.

In one or more twelfth embodiments, further to the eleventh embodiment, the method further comprises removing a portion of the second multilayer fin adjacent a second channel region thereof, recessing the first materials of the second multilayer fin and forming cavity spacers adjacent the recessed first materials, removing the second mask, and epitaxially depositing a second source or drain material comprising a second conductivity type on the second material of the first multilayer fin structure.

In one or more thirteenth embodiments, further to the eleventh or twelfth embodiments, the method further comprises forming, prior to said forming the second mask, a liner material on the source or drain material comprising the first conductivity type, the first liner material comprising oxygen and one or more of silicon, nitrogen, or aluminum.

In one or more fourteenth embodiments, further to any of the eleventh through thirteenth embodiments, the method further comprises removing, subsequent to said forming the second mask, the liner material from over the second multilayer fin structure.

In one or more fifteenth embodiments, further to any of the eleventh through fourteenth embodiments, the source or drain material comprising the first conductivity type comprises silicon, germanium, and a p-type dopant.

In one or more sixteenth embodiments, further to any of the eleventh through fifteenth embodiments, forming the cavity spacers adjacent the recessed first materials comprises depositing a spacer material and etching back the spacer material.

In one or more seventeenth embodiments, further to any of the eleventh through sixteenth embodiments, the method further comprises removing, prior to said removing the portion of the first multilayer fin, a gate spacer material from over the portion of the first multilayer fin, wherein the spacer material and the gate spacer material comprises different material compositions.

In one or more eighteenth embodiments, a of fabricating an integrated circuit structure comprises receiving a first multilayer channel structure and a second multilayer channel structure, the first and second multilayer fin structures comprising alternating first and second material layers, the first material layers recessed relative to the second material layers, blanket depositing a dielectric material on the first and second multilayer channel structures, forming a first mask to selectively expose the first multilayer channel structure and cover the second multilayer channel structure, etching a portion of the dielectric material adjacent the first multilayer channel structure to form cavity spacers comprising the dielectric material adjacent the first material layers of the first multilayer channel structure, removing the first mask, epitaxially depositing a source or drain material comprising a first conductivity type on the second material layers of the first multilayer channel structure, and forming a second mask to selectively expose the second multilayer channel structure and mask the first multilayer channel structure.

In one or more nineteenth embodiments, further to the eighteenth embodiment, the method further comprises etching a second portion of the dielectric material adjacent the second multilayer channel structure to form second cavity spacers comprising the dielectric material adjacent the first material layers of the second multilayer channel structure, removing the second mask, and epitaxially depositing a second source or drain material comprising a second conductivity type on the second material layers of the second multilayer channel structure.

In one or more twentieth embodiments, further to the eighteenth or nineteenth embodiments, the method further comprises forming, prior to said forming the second mask, a liner material on the source or drain material comprising the first conductivity type, the first liner material comprising one or more of silicon, oxygen, nitrogen, or aluminum.

In one or more twenty-first embodiments, further to any of the eighteenth through twentieth embodiments, the method further comprises removing, subsequent to said forming the second mask, the liner material from over the second multilayer channel structure.

In one or more twenty-second embodiments, further to any of the eighteenth through twenty-first embodiments, the method further comprises forming the first and second channel structures by depositing a conformal layer over gate structures over first and second first multilayer fin structures corresponding to the first and second multilayer channel structures, etching portions of the first and second first multilayer fin structures, removing the conformal layer, and recess etching the first material layers.

In one or more twenty-third embodiments, further to any of the eighteenth through twenty-second embodiments, the source or drain material comprising the first conductivity type comprises silicon, germanium, and a p-type dopant.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An integrated circuit device, comprising:
a first source or drain semiconductor of a first conductivity type coupled to a plurality of first channel layers of a first gate-all-around transistor;
a second source or drain semiconductor of a second conductivity type coupled to a plurality of second channel layers of a second gate-all-around transistor, the second source or drain laterally adjacent the first source or drain; and
a dielectric layer extending between the first source or drain semiconductor and the second source or drain semiconductor, the dielectric material over an isolation material between the first and second gate-all-around transistors, the dielectric layer comprising a first thickness at a first position adjacent the first source or drain semiconductor and a second thickness, less than the first thickness, at a second position between the first position and the second source or drain semiconductor.

2. The integrated circuit device of claim 1, wherein the second thickness is not more than half the first thickness.

3. The integrated circuit device of claim 1, wherein the isolation material comprises silicon and oxygen, and the dielectric layer comprises silicon and at least one of oxygen, carbon, or nitrogen.

4. The integrated circuit device of claim 1, wherein the dielectric layer comprises a third thickness, greater than the second thickness, at a third position between the second position and the second source or drain.

5. The integrated circuit device of claim 4, wherein first position and the third position are not more than 10 nm apart in a direction extending between the first and second source or drain.

6. The integrated circuit device of claim 1, wherein the dielectric layer comprises a third thickness, less than the first thickness, at a third position between the first position and the first source or drain.

7. The integrated circuit device of claim 6, wherein first position and the third position are not more than 10 nm apart in a direction extending between the first and second source or drain.

8. The integrated circuit device of claim 1, wherein the dielectric layer comprises a same material as a gate spacer of the first and second gate-all-around transistors.

9. The integrated circuit device of claim 1, wherein the first and second gate-all-around transistors are over a substrate of a monolithic die, the integrated circuit device further comprising a power supply coupled to the monolithic die.

10. A method of fabricating an integrated circuit structure, comprising:
forming a first mask to selectively expose a first multilayer fin structure and cover a second multilayer fin structure, the first and second multilayer fin structures comprising alternating layers of first and second materials;
removing a portion of the first multilayer fin adjacent a channel region thereof;
recessing the first materials of the first multilayer fin and forming cavity spacers adjacent the recessed first materials;
removing the first mask;
epitaxially depositing a source or drain material comprising a first conductivity type on the second material of the first multilayer fin structure; and
forming a second mask to selectively expose the second multilayer fin structure and mask the first multilayer fin structure.

11. The method of claim 10, further comprising:
removing a portion of the second multilayer fin adjacent a second channel region thereof;
recessing the first materials of the second multilayer fin and forming cavity spacers adjacent the recessed first materials;
removing the second mask; and
epitaxially depositing a second source or drain material comprising a second conductivity type on the second material of the first multilayer fin structure.

12. The method of claim 11, further comprising:
forming, prior to said forming the second mask, a liner material on the source or drain material comprising the first conductivity type, the first liner material comprising oxygen and one or more of silicon, nitrogen, or aluminum.

13. The method of claim 12, further comprising:
removing, subsequent to said forming the second mask, the liner material from over the second multilayer fin structure.

14. The method of claim 10, wherein the source or drain material comprising the first conductivity type comprises silicon, germanium, and a p-type dopant.

15. The method of claim 10, wherein forming the cavity spacers adjacent the recessed first materials comprises depositing a spacer material and etching back the spacer material.

16. The method of claim 15, further comprising:
removing, prior to said removing the portion of the first multilayer fin, a gate spacer material from over the portion of the first multilayer fin, wherein the spacer material and the gate spacer material comprises different material compositions.

17. A method of fabricating an integrated circuit structure, comprising:
receiving a first multilayer channel structure and a second multilayer channel structure, the first and second multilayer fin structures comprising alternating first and second material layers, the first material layers recessed relative to the second material layers;
blanket depositing a dielectric material on the first and second multilayer channel structures;
forming a first mask to selectively expose the first multilayer channel structure and cover the second multilayer channel structure;
etching a portion of the dielectric material adjacent the first multilayer channel structure to form cavity spacers comprising the dielectric material adjacent the first material layers of the first multilayer channel structure;
removing the first mask;
epitaxially depositing a source or drain material comprising a first conductivity type on the second material layers of the first multilayer channel structure; and
forming a second mask to selectively expose the second multilayer channel structure and mask the first multilayer channel structure.

18. The method of claim 17, further comprising:
etching a second portion of the dielectric material adjacent the second multilayer channel structure to form second cavity spacers comprising the dielectric material adjacent the first material layers of the second multilayer channel structure;
removing the second mask; and
epitaxially depositing a second source or drain material comprising a second conductivity type on the second material layers of the second multilayer channel structure.

19. The method of claim 18, further comprising:
forming, prior to said forming the second mask, a liner material on the source or drain material comprising the first conductivity type, the first liner material comprising one or more of silicon, oxygen, nitrogen, or aluminum.

20. The method of claim 19, further comprising:
removing, subsequent to said forming the second mask, the liner material from over the second multilayer channel structure.

21. The method of claim 17, further comprising forming the first and second channel structures by:
depositing a conformal layer over gate structures over first and second first multilayer fin structures corresponding to the first and second multilayer channel structures;
etching portions of the first and second first multilayer fin structures;
removing the conformal layer; and
recess etching the first material layers.

22. The method of claim 17, wherein the source or drain material comprising the first conductivity type comprises silicon, germanium, and a p-type dopant.
